(19) United States
(12) Patent Application Publication
(10) Pub. No.: US 2025/0294947 A1
(43) Pub. Date: Sep. 18, 2025

(54) DISPLAY DEVICE AND METHOD OF MANUFACTURING THE SAME

(71) Applicant: Samsung Display Co., LTD., Yongin-si (KR)

(72) Inventors: Jin Seok PARK, Yongin-si (KR); Chae Woo CHUNG, Yongin-si (KR); Min Woo KIM, Yongin-si (KR); Hoo Keun PARK, Yongin-si (KR)

(21) Appl. No.: 18/967,450

(22) Filed: Dec. 3, 2024

(30) Foreign Application Priority Data
Mar. 18, 2024 (KR) 10-2024-0036892

(51) Int. Cl. H10H 29/80; H10H 29/01; H10H 29/24

(52) U.S. Cl. CPC H10H 29/8321; H10H 29/012; H10H 29/24; H10H 29/882

(57) ABSTRACT

A display device includes a pixel electrode, a light emitting element including a first semiconductor layer, an active layer, and a second semiconductor layer sequentially located on the pixel electrode, a groove being in a portion of the light emitting element where the second semiconductor layer is located, a common electrode on the light emitting element, and a light scattering layer on the common electrode and filling the groove.

### CROSS-REFERENCE TO RELATED APPLICATION

The present application claims priority to and the benefit of Korean Patent Application No. 10-2024-0036892, filed on Mar. 18, 2024, in the Korean Intellectual Property Office, the entire disclosure of which is incorporated by reference herein.

### BACKGROUND

### 1. Field

The present disclosure relates to a display device and a method of manufacturing the same.

### 2. Description of the Related Art

As the information society develops, demands for display devices for displaying images are increasing in various forms. Accordingly, various types of display devices including light emitting display devices are being developed. A light emitting display device includes a light emitting element.

### SUMMARY

Aspects and features of embodiments of the present disclosure provide a display device, which can increase the light output efficiency of a light emitting element and improve a driving voltage, and a method of manufacturing the display device.

However, aspects and features of embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device including, a pixel electrode, a light emitting element including a first semiconductor layer, an active layer, and a second semiconductor layer sequentially located on the pixel electrode, a groove being in a portion of the light emitting element where the second semiconductor layer is located, a common electrode on the light emitting element, and a light scattering layer on the common electrode and filling the groove.

In one or more embodiments, the second semiconductor layer may include a first portion including a bottom surface of the groove and a second portion on the first portion, wherein a doping concentration of the first portion may be higher than a doping concentration of the second portion.

In one or more embodiments, the common electrode may contact the first portion of the second semiconductor layer.

In one or more embodiments, the second portion of the second semiconductor layer may include a portion of a sidewall of the groove.

In one or more embodiments, the light emitting element may further include a protective layer covering side surfaces of the first semiconductor layer, the active layer and the second semiconductor layer, wherein a portion of the protective layer may protrude above a height of the second semiconductor layer and surround the groove.

In one or more embodiments, the groove may be formed at a position spaced from the active layer by 0.5 μm or more.

In one or more embodiments, a bottom surface of the groove may be located at a height of 0.5 to 1.5 μm from an upper surface of the active layer.

In one or more embodiments, the common electrode may have a shape corresponding to that of the groove, and a portion of the common electrode may be inside the groove.

In one or more embodiments, a bottom surface of the groove may include a textured pattern, and the common electrode and the light scattering layer may include a light transmission pattern having a shape corresponding to that of the textured pattern on the bottom surface of the groove.

In one or more embodiments, the light emitting element may further include a first reflective layer under the first semiconductor layer.

In one or more embodiments, the first reflective layer may include metal.

In one or more embodiments, a portion of the first reflective layer may cover side surfaces of the first semiconductor layer, the active layer, and the second semiconductor layer.

In one or more embodiments, the light emitting element may further include a second reflective layer covering the side surfaces of the first semiconductor layer, the active layer, and the second semiconductor layer.

In one or more embodiments, the second reflective layer may include a distributed Bragg reflector.

In one or more embodiments, the light scattering layer may include light scatterers.

In one or more embodiments, the light scattering layer may further include wavelength conversion particles.

In one or more embodiments, the display device may further include a light conversion layer on the light emitting element and the light scattering layer, and including wavelength conversion particles.

According to one or more embodiments of the present disclosure, there is provided a method of manufacturing a display device, the method including, forming a thin-film transistor layer including a substrate and a thin-film transistor and forming a pixel electrode on the thin-film transistor layer, preparing a light emitting element including a first semiconductor layer, an active layer and a second semiconductor layer and placing the light emitting element on the pixel electrode such that the second semiconductor layer faces upward, forming a groove in the light emitting element by etching the second semiconductor layer, forming a common electrode on the light emitting element, and forming a light scattering layer on the common electrode to fill the groove.

In one or more embodiments, the second semiconductor layer of the light emitting element may include a first portion on the active layer and having a first doping concentration and a second portion on the first portion and having a second doping concentration lower than the first doping concentration, wherein the second semiconductor layer may be etched to expose the first portion in the forming of the groove in the light emitting element.

In one or more embodiments, the common electrode may contact the first portion of the second semiconductor layer.

According to one or more embodiments of the present disclosure, there is provided an electronic device for providing an image, including a display device, the display device including, a pixel electrode, a light emitting element including a first semiconductor layer, an active layer, and a second semiconductor layer sequentially located on the pixel electrode, a groove being in a portion of the light emitting element where the second semiconductor layer is located, a common electrode on the light emitting element, and a light scattering layer on the common electrode and filling the groove.

A display device according to one or more embodiments includes a light emitting element including a groove in a portion where a second semiconductor layer is disposed, a common electrode disposed on the light emitting element, and a light scattering layer disposed on the common electrode and filling the groove. According to the display device and a method of manufacturing the display device according to one or more embodiments, the amount of light emitted to above the light emitting device can be increased by appropriately scattering or diffusing light emitted from the light emitting element. In addition, the light output efficiency of the light emitting element can be increased by reducing a distance between an active layer and a light output surface of the light emitting element.

In some embodiments, a groove of the light emitting element may be formed to a depth that exposes a high-doped layer of the second semiconductor layer, and the common electrode may contact the high-doped layer. According to the display device and the method of manufacturing the display device according to the embodiments, the electrical connection, e.g., ohmic contact between the light emitting element and the common electrode can be improved, and a driving voltage of the display device can be improved. Accordingly, the reliability of the display device can be increased, and the power consumption of the display device can be improved.

However, effects according to the embodiments of the present disclosure are not limited to those exemplified above and various other effects are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to one or more embodiments;

FIG. 2 is a layout view of a display device according to one or more embodiments;

FIG. 3 is a block diagram of a display device according to one or more embodiments;

FIG. 4 is an equivalent circuit diagram of a subpixel according to one or more embodiments;

FIG. 5 is a layout view illustrating pixels of a display area according to one or more embodiments;

FIG. 6 is a cross-sectional view illustrating an example of a cross section of a display panel corresponding to the line I1-I1′ of FIG. 5;

FIG. 7 is a detailed cross-sectional view of an example of an area A of FIG. 6;

FIG. 8 is a cross-sectional view illustrating an example of a cross section of a display panel corresponding to the line I1-I1′ of FIG. 5;

FIG. 9 is a cross-sectional view illustrating an example of a cross section of a display panel corresponding to the line I1-I1′ of FIG. 5;

FIG. 10 is a cross-sectional view illustrating an example of a cross section of a display panel corresponding to the line I1-I1′ of FIG. 5;

FIG. 11 is a detailed cross-sectional view of an example of an area B of FIG. 8;

FIG. 12 is a graph illustrating the carrier doping concentration of a second semiconductor layer according to one or more embodiments;

FIG. 13 is a detailed cross-sectional view of an example of the area B of FIG. 8;

FIG. 14 is a detailed cross-sectional view of an example of the area B of FIG. 8;

FIG. 15 is a detailed cross-sectional view of an example of the area B of FIG. 8;

FIG. 16 is a detailed cross-sectional view of an example of the area B of FIG. 8;

FIG. 17 is a detailed cross-sectional view of an example of the area B of FIG. 8;

FIG. 18 is a detailed cross-sectional view of an example of the area B of FIG. 8;

FIG. 19 is a detailed cross-sectional view of an example of the area B of FIG. 8;

FIG. 20 is a cross-sectional view illustrating an example of a cross section of a display panel corresponding to the line I1-I1′ of FIG. 5;

FIGS. 21 through 30 are cross-sectional views illustrating a method of manufacturing a display device according to one or more embodiments;

FIG. 31 is an example view of a smart watch including a display device according to one or more embodiments;

FIGS. 32 and 33 are example views of a virtual reality (VR) device including a display device according to one or more embodiments;

FIG. 34 is an example view of a VR device including a display device according to one or more embodiments;

FIG. 35 is an example view illustrating a vehicle instrument cluster and center fascia including display devices according to one or more embodiments; and

FIG. 36 is an example view of a transparent display device including a display device according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, and/or combinations thereof.

As used herein, “directly disposed” may mean that there is no layer, film, region, plate, etc. added between a portion such as a layer, film, region, or plate and another portion. For example, “directly disposed” may mean that two layers or two members are disposed without using an additional member such as an adhesive member therebetween.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized and/or overly formal sense unless expressly so defined herein.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, a display panel according to one or more embodiments of the present disclosure and a manufacturing method of a display panel will be described with reference to the accompanying drawings.

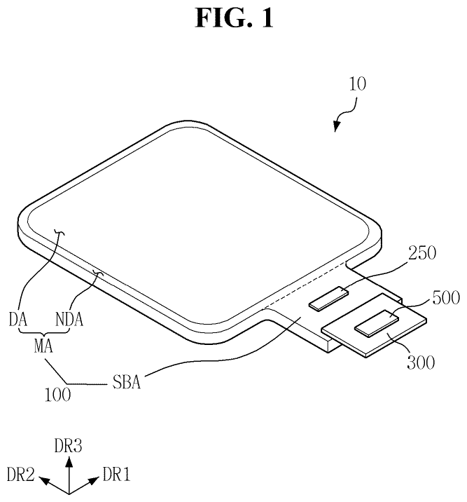

FIG. 1 is a perspective view of a display device 10 according to one or more embodiments.

Referring to FIG. 1, the display device 10 is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and Internet of things (loT) devices.

The display device 10 may be a light emitting display device such as an organic light emitting display device using an organic light emitting diode (OLED), a quantum dot light emitting display device including a quantum dot light emitting layer, an inorganic light emitting display device including an inorganic semiconductor, or a micro- or nano-light emitting display device using a micro- or nano-light emitting diode (LED). A case where the display device 10 is a micro- or nano-light emitting display device will be mainly described below, but the present disclosure is not limited thereto. For ease of description, a micro- or nano-LED will be referred to as a light emitting element.

The display device 10 includes a display panel 100, a display driving circuit 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape but may also be other polygonal shapes, a circular shape, and/or an elliptical shape. The display panel 100 may be formed flat, but the present disclosure is not limited thereto. For example, the display panel 100 may include a curved portion formed at left and right ends and having a constant or varying curvature. In addition, the display panel 100 may be formed to be flexible so that it can be curved, bent, folded, and/or rolled.

The display panel 100 may include a main area MA and a sub-area SBA.

The main area MA may include a display area DA that displays an image and a non-display area NDA disposed around the display area DA along an edge or a periphery of the display area DA. The display area DA may include a plurality of pixels, which display an image. Each of the pixels may include a plurality of subpixels. For example, each of the pixels may include a first subpixel which emits first light, a second subpixel which emits second light, and a third subpixel that emits third light, but the present disclosure is not limited thereto.

The sub-area SBA may protrude from a side of the main area MA in the second direction DR2. Although the sub-area SBA is unfolded in FIG. 1, it may be bent. In this case, the sub-area SBA may be placed on a lower surface of the display panel 100. When the sub-area SBA is bent, it may be overlapped by the main area MA in a third direction DR3, which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached onto the display panel 100 using a chip on glass (COG) method, a chip on plastic (COP) method, and/or an ultrasonic bonding method. However, the present disclosure is not limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), and/or a flexible film such as a chip on film (COF).

The power supply unit 500 may generate a plurality of panel driving voltages according to a power supply voltage from the outside. The power supply unit 500 may be formed as an integrated circuit (IC) and attached onto the circuit board 300 using a COF method.

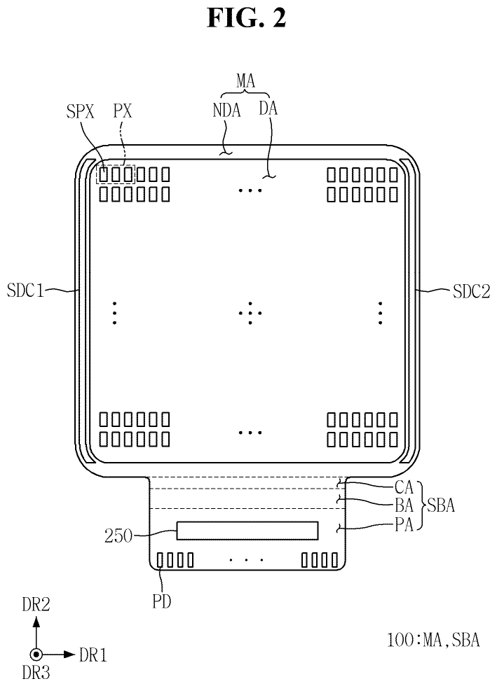

FIG. 2 is a layout view of the display device 10 according to one or more embodiments. FIG. 2 illustrates a state in which the sub-area SBA is unfolded without being bent.

Referring to FIG. 2, the display panel 100 may include the main area MA and the sub-area SBA.

The main area MA may include the display area DA that displays an image and the non-display area NDA disposed around the display area DA. The display area DA may occupy most of the main area MA. The display area DA may be disposed in a center of the main area MA.

The display area DA may include a plurality of pixels PX for displaying an image, and each of the pixels PX may include a plurality of subpixels SPX. A pixel PX may be defined as a smallest subpixel group that can express a white gray level.

The non-display area NDA may neighbor the display area DA. The non-display area NDA may be an area outside the display area DA. The non-display area NDA may surround the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, the present disclosure is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driving circuit 250 are disposed. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may contact the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may contact the connection area CA, and the other side of the bending area BA may contact the pad area PA.

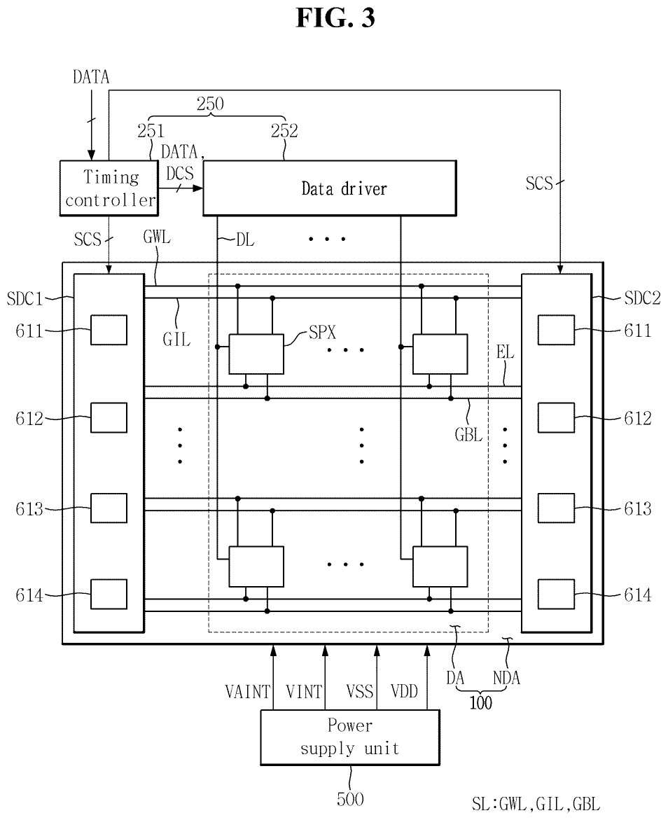

FIG. 3 is a block diagram of the display device 10 according to one or more embodiments.

Referring to FIG. 3, the display area DA includes a plurality of pixels PX, a plurality of scan lines SL, a plurality of emission control lines EL, and a plurality of data lines DL.

The pixels PX may be arranged in a matrix form along the first direction DR1 and the second direction DR2. For example, the pixels PX may be arranged along rows and columns of a matrix along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. The scan lines SL include a plurality of write scan lines GWL, a plurality of initialization scan lines GIL, and a plurality of bias scan lines GBL.

Each of the subpixels SPX may be connected to one of the write scan lines GWL, one of the initialization scan lines GIL, one of the bias scan lines GBL, one of the emission control lines EL, and one of the data lines DL. Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, an initialization scan signal output unit 612, a bias scan signal output unit 613, and an emission control signal output unit 614. Each of the write scan signal output unit 611, the initialization scan signal output unit 612, the bias scan signal output unit 613, and the emission control signal output unit 614 may receive a scan timing control signal SCS from a timing controller 251 of the display driving circuit 250.

The write scan signal output unit 611 may generate write scan signals according to the scan timing control signal SCS of the timing controller 251 and sequentially output the write scan signals to the write scan lines GWL.

The initialization scan signal output unit 612 may generate initialization scan signals according to the scan timing control signal SCS and sequentially output the initialization scan signals to the initialization scan lines GIL.

The bias scan signal output unit 613 may generate bias scan signals according to the scan timing control signal SCS and sequentially output the bias scan signals to the bias scan lines GBL. The emission control signal output unit 614 may generate emission control signals according to the scan timing control signal SCS and sequentially output the emission control signals to the emission control lines EL.

The display driving circuit 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage supplied from the outside. For example, the power supply unit 500 may generate a first power supply voltage VDD, a second power supply voltage VSS, a third power supply voltage VINT, and a fourth power supply voltage VAINT, and supply them to the display panel 100.

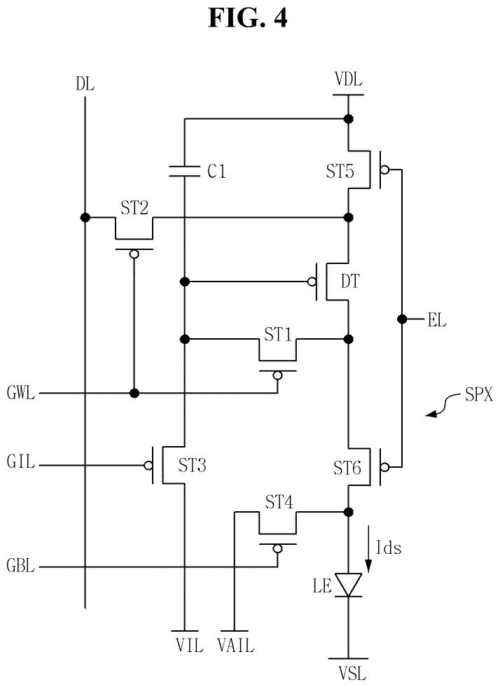

FIG. 4 is an equivalent circuit diagram of a subpixel SPX according to one or more embodiments.

Referring to FIG. 4, the subpixel SPX according to one or more embodiments may be connected to scan lines GWL, GIL, and GBL, an emission control line EL, and a data line DL. For example, the subpixel SPX may be connected to a write scan line GWL, an initialization scan line GIL, a bias scan line GBL, the emission control line EL, and the data line DL.

The subpixel SPX according to the embodiment includes a driving transistor DT, switch elements, a capacitor C1, and a light emitting element LE. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode of the driving transistor DT according to a data voltage applied to the gate electrode of the driving transistor DT.

The light emitting element LE may be a micro-LED.

The light emitting element LE emits light according to the driving current Ids. The amount of light emitted from the light emitting element LE may be proportional to the driving current Ids. An anode of the light emitting element LE may be connected to a first electrode of the fourth transistor ST4 and a second electrode of the sixth transistor ST6, and a cathode may be connected to a second power line VSL to which the second power supply voltage VSS (see FIG. 3) is applied.

The capacitor C1 is formed between the gate electrode of the driving transistor DT and a first power line VDL to which the first power supply voltage VDD (see FIG. 3) is applied. The first power supply voltage VDD may be at a higher level than the second power supply voltage VSS. One electrode of the capacitor C1 may be connected to the gate electrode of the driving transistor DT, and the other electrode may be connected to the first power line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, and a gate electrode of the fourth transistor ST4 may be connected to the bias scan line GBL. Because the first through sixth transistors ST1 through ST6 are formed as p-type MOSFETs, they may be turned on when a scan signal of a gate-low voltage and an emission control signal are transmitted to the initialization scan line GIL, the write scan line GWL, the bias scan line GBL, and the emission control line EL. One electrode of the third transistor ST3 may be connected to a first initialization voltage line VIL to which the third power supply voltage VINT (see FIG. 3) is applied, and one electrode of the fourth transistor ST4 may be connected to a second initialization voltage line VAIL to which the fourth power supply voltage VAINT (see FIG. 3) is applied. The third power supply voltage VINT (see FIG. 3) and the fourth power supply voltage VAINT (see FIG. 3) may be different voltages. In addition, the third power supply voltage VINT (see FIG. 3) and the fourth power supply voltage VAINT (see FIG. 3) may be at a lower level than the first power supply voltage VDD and may be at a higher level than the second power supply voltage VSS.

Alternatively, the driving transistor DT, the second transistor ST2, the fourth transistor ST4, the fifth transistor ST5, and the sixth transistor ST6 may be formed as p-type MOSFETs, and the first transistor ST1 and the third transistor ST3 may be formed as n-type MOSFETs. In this case, the active layer of each of the driving transistor DT, the second transistor ST2, the fourth transistor ST4, the fifth transistor ST5, and the sixth transistor ST6 formed as p-type MOSFETs may be made of polysilicon, and the active layer of each of the first transistor ST1 and the third transistor ST3 formed as n-type MOSFETs may be made of an oxide semiconductor. In addition, because the first transistor ST1 and the third transistor ST3 are formed as n-type MOSFETs, the first transistor ST1 may be turned on in response to a scan signal of a gate-high voltage, and the third transistor ST3 may be turned on in response to an initialization scan signal of a gate-high voltage. On the other hand, because the second transistor ST2, the fourth transistor ST4, the fifth transistor ST5, and the sixth transistor ST6 are formed as p-type MOSFETs, they may be turned on in response to a scan signal of a gate-low voltage and an emission control signal.

Alternatively, the fourth transistor ST4 may be formed as an n-type MOSFET, and the other transistors DT, ST1, ST2, ST3, ST5, and ST6 may be formed as p-type MOSFETs. In this case, the active layer of the fourth transistor ST4 may be made of an oxide semiconductor, and the active layer of each of the other transistors DT, ST1, ST2, ST3, ST5, and ST6 may be made of polysilicon. In addition, the fourth transistor ST4 may be turned on in response to a scan signal of a gate-high voltage, and the other transistors DT, ST1, ST2, ST3, ST5, and ST6 may be turned on in response to a scan signal of a gate-low voltage and an emission control signal.

Alternatively, the first through sixth transistors ST1 through ST6 and the driving transistor DT may all be formed as n-type MOSFETs. In this case, the first through sixth transistors ST1 through ST6 and the driving transistor DT may each have the active layer made of an oxide semiconductor and may be turned on in response to a scan signal of a gate-high voltage and an emission control signal.

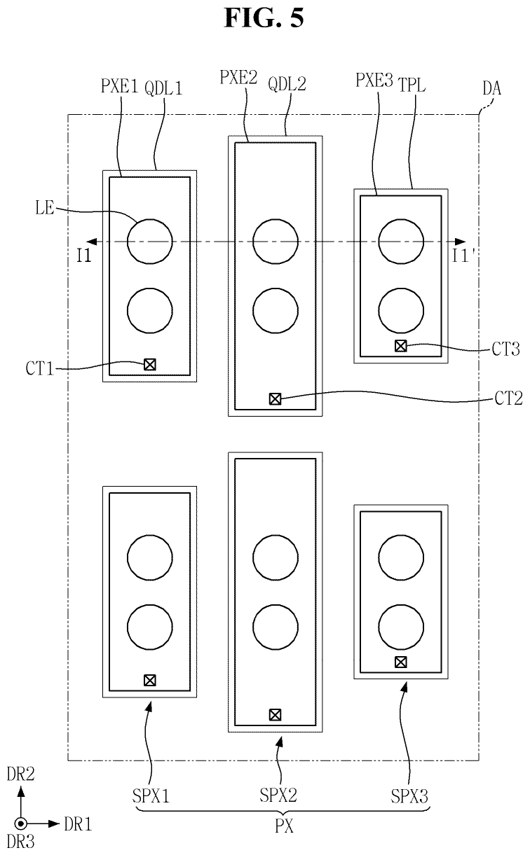

FIG. 5 is a layout view illustrating pixels PX of a display area DA according to one or more embodiments.

Referring to FIG. 5, each of the pixels PX in the display area DA may include three subpixels SPX1 through SPX3. However, the present disclosure is not limited thereto, and each of the pixels PX may also include four subpixels. When each of the pixels PX includes three subpixels SPX1 through SPX3, it may include a first subpixel SPX1, a second subpixel SPX2, and a third subpixel SPX3.

The pixels PX may be arranged in a matrix form. In each of the pixels PX, the first subpixel SPX1, the second subpixel SPX2, and the third subpixel SPX3 may be arranged along the first direction DR1.

When each of the pixels PX includes three subpixels SPX1 through SPX3, the first subpixel SPX1 may output first light, the second subpixel SPX2 may output second light, and the third subpixel SPX3 may output third light. Here, the first light may be light in a blue wavelength band, the second light may be light in a green wavelength band, and the third light may be light in a red wavelength band. For example, the blue wavelength band may indicate that a main peak wavelength of light is included in a wavelength band of about 370 to 460 nm, the green wavelength band may indicate that a main peak wavelength of light is included in a wavelength band of about 480 to 560 nm, and the red wavelength band may indicate that a main peak wavelength of light is included in a wavelength band of about 600 to 750 nm.

Alternatively, when each of the pixels PX includes four subpixels, a first subpixel may output first light, a second subpixel and a fourth subpixel may output second light, and a third subpixel may output third light. Alternatively, the first subpixel may output first light, the second subpixel may output second light, the third subpixel may output third light, and the fourth subpixel may output fourth light. Here, the fourth light may be white light.

The first subpixel SPX1 includes a first pixel electrode PXE1, a plurality of light emitting elements LE, and a first light conversion layer QDL1. The second subpixel SPX2 includes a second pixel electrode PXE2, a plurality of light emitting elements LE, and a second light conversion layer QDL2. The third subpixel SPX3 includes a third pixel electrode PXE3, a plurality of light emitting elements LE, and a light transmission layer (or a third light conversion layer) TPL.

Each of the first pixel electrode PXE1, the second pixel electrode PXE2, and the third pixel electrode PXE3 may be shaped like a rectangular plane having short sides in the first direction DR1 and long sides in the second direction DR2. The area of the first subpixel SPX1, the area of the second subpixel SPX2, and the area of the third subpixel SPX3 may be set according to the light conversion efficiency of the first light conversion layer QDL1 and the light conversion efficiency of the second light conversion layer QDL2. For example, the lower the light conversion efficiency, the larger the area of a subpixel.

For example, as illustrated in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1. In addition, because the first light conversion layer QDL1 must convert light whereas the light transmission layer TPL transmits light of the light emitting elements LE as it is, the area of the first pixel electrode PXE1 may be larger than the area of the third pixel electrode PXE3.

Each of the pixel electrodes PXE1 through PXE3 may be electrically connected to at least one transistor through a pixel connection hole CT1/CT2/CT3. For example, each of the pixel electrodes PXE1 through PXE3 may be electrically connected to the first electrode of the fourth transistor ST4 (see FIG. 4) and the second electrode of the sixth transistor ST6 (see FIG. 4) of a corresponding subpixel.

A plurality of light emitting elements LE may be disposed on each of the pixel electrodes PXE1 through PXE3. The same number of light emitting elements LE may be disposed on each of the pixel electrodes PXE1 through PXE3. For example, two light emitting elements LE may be disposed on each of the pixel electrodes PXE1 through PXE3. The light emitting elements LE may emit third light, for example, light in the blue wavelength band, but the present disclosure is not limited thereto. If the light emitting elements LE of the first subpixel SPX1 emit first light, the light emitting elements LE of the second subpixel SPX2 emit second light, and the light emitting elements LE of the third subpixel SPX3 emit third light, the light conversion layers QDL1 and QDL2 and the light transmission layer TPL may be omitted.

The first light conversion layer QDL1 may completely overlap the first pixel electrode PXE1 and the light emitting elements LE of the first subpixel SPX1. The area of the first light conversion layer QDL1 may be larger than the area of the first pixel electrode PXE1. The first light conversion layer QDL1 may convert or shift a peak wavelength of incident light into light of another specific peak wavelength and output the light of the specific peak wavelength. For example, the first light conversion layer QDL1 may convert or shift third light emitted from the light emitting elements LE of the first subpixel SPX1 into first light.

The second light conversion layer QDL2 may completely overlap the second pixel electrode PXE2 and the light emitting elements LE of the second subpixel SPX2. The area of the second light conversion layer QDL2 may be larger than the area of the second pixel electrode PXE2. The second light conversion layer QDL2 may convert or shift a peak wavelength of incident light into light of another specific peak wavelength and output the light of the specific peak wavelength. For example, the second light conversion layer QDL2 may convert or shift third light emitted from the light emitting elements LE of the second subpixel SPX2 into second light.

The light transmission layer TPL may completely overlap the third pixel electrode PXE3 and the light emitting elements LE of the third subpixel SPX3. The light transmission layer TPL may transmit incident light as it is. For example, the light transmission layer TPL may transmit third light emitted from the light emitting elements LE of the third subpixel SPX3 as it is.

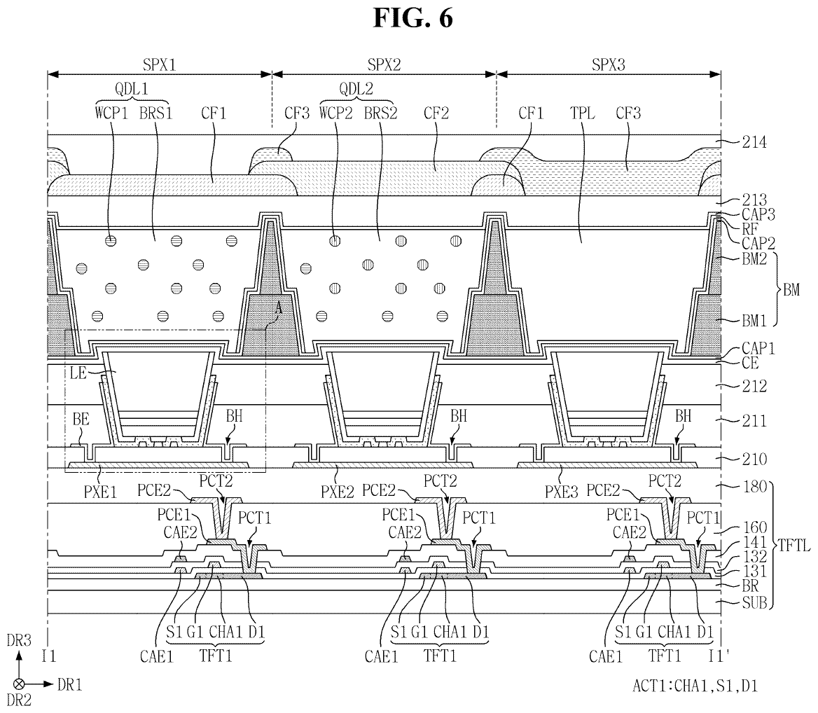

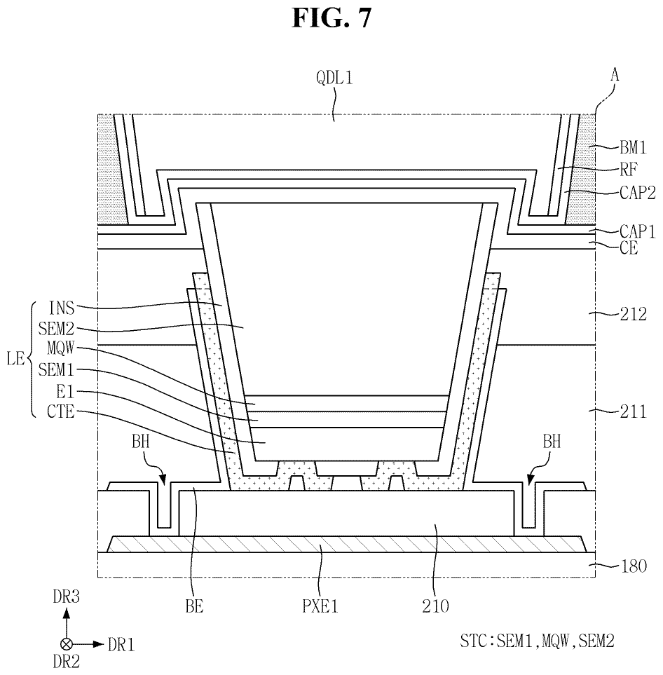

FIG. 6 is a cross-sectional view illustrating an example of a cross section of the display panel 100 corresponding to line I1-I1′ of FIG. 5. FIG. 7 is a detailed cross-sectional view of an example of an area A of FIG. 6.

Referring to FIGS. 6 and 7, a substrate SUB may be made of an insulating material such as glass and/or polymer resin. When the substrate SUB is made of polymer resin, it may be a flexible substrate that can be stretched. The polymer resin may be acryl resin, epoxy resin, phenolic resin, polyamide resin, and/or polyimide resin.

A barrier layer BR may be disposed on the substrate SUB. The barrier layer BR is a layer for protecting transistors of a thin-film transistor layer TFTL and light emitting elements LE disposed on the thin-film transistor layer TFTL from moisture introduced through the substrate SUB which is vulnerable to moisture penetration. The barrier layer BR may be composed of a plurality of inorganic layers stacked alternately. Thin-film transistors TFT1 may be disposed on the barrier layer BR. Each of the thin-film transistors TFT1 may be the fourth transistor ST4 or the sixth transistor ST6 illustrated in FIG. 4. Each of the thin-film transistors TFT1 may include a first active layer ACT1 and a first gate electrode G1.

The first active layer ACT1 of each of the thin-film transistors TFT1 may be disposed on the barrier layer BR. The first active layer ACT1 of each of the thin-film transistors TFT1 may include polycrystalline silicon, monocrystalline silicon, low-temperature polycrystalline silicon, and/or amorphous silicon. Alternatively, the first active layer ACT1 of each of the thin-film transistors TFT1 may be made of an oxide semiconductor including IGZO (indium (In), gallium (Ga), zinc (Zn) and oxygen (O)), IGZTO (indium (In), gallium (Ga), zinc (Zn), tin (Sn) and oxygen (O)), and/or IGTO (indium (In), gallium (Ga), tin (Sn) and oxygen (O)).

The first active layer ACT1 may include a first channel region CHA1, a first source region S1, and a first drain region D1. The first channel region CHA1 may be a region overlapped by the first gate electrode G1 in the third direction DR3, which is the thickness direction of the substrate SUB. The first source region S1 may be disposed on a side of the first channel region CHA1, and the first drain region D1 may be disposed on the other side of the first channel region CHA1. The first source region S1 and the first drain region D1 may be regions not overlapped by the first gate electrode G1 in the third direction DR3. The first source region S1 and the first drain region D1 may be regions formed to have conductivity by doping a semiconductor material with ions.

A first gate insulating layer 131 may be disposed on the first channel regions CHA1, the first source regions S1, and the first drain regions D1 of the thin-film transistors TFT1 and the barrier layer BR.

A first gate metal layer may be disposed on the first gate insulating layer 131. The first gate metal layer may include the first gate electrodes G1 of the thin-film transistors TFT1 and first capacitor electrodes CAE1. The first gate electrodes G1 may overlap the first active layers ACT1 in the third direction DR3. In FIG. 6, the first gate electrodes G1 and the first capacitor electrodes CAE1 are spaced (e.g., spaced apart) from each other. However, when each of the thin-film transistors TFT1 is the driving transistor DT of FIG. 4, the first gate electrodes G1 and the first capacitor electrodes CAE1 may be electrically or physically connected to each other. Alternatively, when each of the thin-film transistors TFT1 is one of the first through sixth transistors ST1 through ST6 of FIG. 4, the first gate electrodes G1 and the first capacitor electrodes CAE1 may not be electrically or physically connected to each other.

A second gate insulating layer 132 may be disposed on the first gate electrodes G1 of the thin-film transistors TFT1, the first capacitor electrodes CAE1, and the first gate insulating layer 131.

A second gate metal layer may be disposed on the second gate insulating layer 132. The second gate metal layer may include second capacitor electrodes CAE2. The second capacitor electrodes CAE2 may overlap the first capacitor electrodes CAE1 of the thin-film transistors TFT1 in the third direction DR3. Because the second gate insulating layer 132 has a suitable dielectric constant (e.g., a predetermined dielectric constant), capacitors C1 (see FIG. 4) may be formed by the first capacitor electrodes CAE1, the second capacitor electrodes CAE2, and the second gate insulating layer 132 disposed between them.

An interlayer insulating layer 141 may be disposed on the second capacitor electrodes CAE2 and the second gate insulating layer 132.

A first data metal layer may be disposed on the interlayer insulating layer 141. The first data metal layer may include first source connection electrodes PCE1. The first source connection electrodes PCE1 may be connected to the first drain regions D1 of the first active layers ACT1 through first source contact holes PCT1 penetrating the first gate insulating layer 131, the second gate insulating layer 132, and the interlayer insulating layer 141.

A first planarization layer 160 may be disposed on the first source connection electrodes PCE1 and the interlayer insulating layer 141 to flatten steps caused by the thin-film transistors TFT1.

A second data metal layer may be disposed on the first planarization layer 160. The second data metal layer may include second source connection electrodes PCE2. The second source connection electrodes PCE2 may be connected to the first source connection electrodes PCE1 through second source contact holes PCT2 penetrating the first planarization layer 160.

A second planarization layer 180 may be disposed on the second source connection electrodes PCE2 and the first planarization layer 160.

The barrier layer BR, the first gate insulating layer 131, the second gate insulating layer 132, and the interlayer insulating layer 141 may be made of an inorganic layer, for example, silicon nitride (SiNₓ), silicon oxynitride (SiON), silicon oxide (SiOₓ), titanium oxide (TiOₓ), and/or aluminum oxide (AlOₓ).

The first gate metal layer, the second gate metal layer, the first data metal layer, and the second data metal layer may each be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

The first planarization layer 160 and the second planarization layer 180 may be made of an organic layer such as acryl resin, epoxy resin, phenolic resin, polyamide resin, and/or polyimide resin.

The thin-film transistor layer TFTL may include the substrate SUB, the barrier layer BR, the first gate insulating layer 131, the second gate insulating layer 132, the interlayer insulating layer 141, the thin-film transistors TFT1, first gate metal layer, the second gate metal layer, the first data metal layer, the second data metal layer, the first planarization layer 160, and the second planarization layer 180.

A light emitting element layer may be disposed on the second planarization layer 180. The light emitting element layer may include pixel electrodes PXE1 through PXE3, light emitting elements LE, a common electrode CE, and organic layers 210, 211, and 212.

A pixel electrode layer may be disposed on the second planarization layer 180. The pixel electrode layer may include a first pixel electrode PXE1, a second pixel electrode PXE2, and a third pixel electrode PXE3. In one or more embodiments, each of the pixel electrodes PXE1 through PXE3 may be connected to a second source connection electrode PCE2 through a corresponding pixel connection hole CT1/CT2/CT3 (see FIG. 5) penetrating the second planarization layer 180. Each of the pixel electrodes PXE1 through PXE3 may be connected to the first source region S1 or the first drain region D1 of a thin-film transistor TFT1 through a first source connection electrode PCE1 and a second source connection electrode PCE2. Therefore, a voltage controlled by a thin-film transistor TFT1 may be applied to each of the pixel electrodes PXE1 through PXE3.

The pixel electrode layer may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof. For example, the pixel electrode layer may be made of copper (Cu) with low sheet resistance in order to lower the resistance of each of the pixel electrodes PXE1 through PXE3.

A first organic layer 210 may be disposed on each of the pixel electrodes PXE1 through PXE3 and the second planarization layer 180. The first organic layer 210 temporarily fixes or attaches a plurality of light emitting elements LE to prevent the light emitting elements LE from tilting or falling during a process of transferring the light emitting elements LE to the display panel 100. That is, the first organic layer 210 may be a layer for temporarily attaching a plurality of light emitting elements LE onto each of the pixel electrodes PXE1 through PXE3. To facilitate the temporary adhesion, the first organic layer 210 may be thicker than each of the pixel electrodes PXE1 through PXE3 and thicker than contact electrodes CTE.

The first organic layer 210 may be a photosensitive organic layer such as photoresist. Alternatively, the first organic layer 210 may be made of acryl resin, epoxy resin, phenolic resin, polyamide resin, and/or polyimide resin.

The light emitting elements LE may be disposed on the first organic layer 210. In FIG. 6, each of the light emitting elements LE is a vertical type micro-LED extending in the third direction DR3. The vertical type micro-LED refers to an LED having a structure in which a first semiconductor layer SEM1, an active layer MQW, and a second semiconductor layer SEM2, are sequentially disposed in the third direction DR3, which is a vertical direction.

Each of the light emitting elements LE may have a reverse-tapered cross-sectional shape. For example, each of the light emitting elements LE may have a trapezoidal cross-sectional shape whose upper surface is wider than a lower surface.

Each of the light emitting elements LE may be made of an inorganic material such as gallium nitride (GaN). Each of the light emitting elements LE may have a length of several to hundreds of μm in each of the first direction DR1, the second direction DR2, and the third direction DR3. For example, each of the light emitting elements LE may have a length of about 100 μm or less in each of the first direction DR1, the second direction DR2, and the third direction DR3.

Each of the light emitting elements LE may be grown on a semiconductor substrate such as a silicon substrate and/or a sapphire substrate. The light emitting elements LE may be directly transferred from the semiconductor substrate onto the pixel electrodes PXE1 through PXE3 of the display panel 100. Alternatively, the light emitting elements LE may be transferred onto the pixel electrodes PXE1 through PXE3 of the display panel 100 through an electrostatic method using an electrostatic head or a stamp method using an elastic polymer material, such as PDMS and/or silicon, as a transfer substrate.

Each of the light emitting elements LE may include a conductive layer E1, a semiconductor stack STC, contact electrodes (or a single contact electrode) CTE, and a protective layer INS. The semiconductor stack STC may include the first semiconductor layer SEM1, the active layer MQW, and the second semiconductor layer SEM2 sequentially disposed along the third direction DR3.

The conductive layer E1 may be disposed on a lower surface of the first semiconductor layer SEM1. Although the conductive layer E1 covers the entire lower surface of the first semiconductor layer SEM1 in FIG. 7, the present disclosure is not limited thereto. For example, the conductive layer E1 may also be disposed on a portion of the lower surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the conductive layer E1. A length of the lower surface of the first semiconductor layer SEM1 in the first direction DR1 or in the second direction DR2 may be smaller than a length of contact electrodes CTE in the first direction DR1 or in the second direction DR2. The first semiconductor layer SEM1 may be made of a semiconductor material layer, for example, gallium nitride (GaN) doped with a first conductivity type dopant such as magnesium (Mg), zinc (Zn), calcium (Ca), strontium (Sr), and/or barium (Ba).

The active layer MQW may be disposed on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include gallium nitride (GaN), indium gallium nitride (InGaN), and/or aluminum gallium nitride (AlGaN). The active layer MQW may emit light through combination of electron-hole pairs according to electrical signals received through the first semiconductor layer SEM1 and the second semiconductor layer SEM2.

The active layer MQW may include a material having a single or multiple quantum well structure. When the active layer MQW includes a material having a multiple quantum well structure, it may be a structure in which a plurality of well layers and a plurality of barrier layers are alternately stacked. Here, the well layers may be made of InGaN, and the barrier layers may be made of GaN and/or AlGaN, but the present disclosure is not limited thereto. Alternatively, the active layer MQW may be a structure in which a semiconductor material having a large band gap energy and a semiconductor material having a small band gap energy are alternately stacked or may include different group III to V semiconductor materials depending on the wavelength band of light that it emits.

When the active layer MQW includes indium gallium nitride (InGaN), the color of light that it emits may vary according to indium content. For example, as the indium content increases, the wavelength band of light emitted from the active layer MQW may move to the red wavelength band, and as the indium content decreases, the wavelength band of light emitted from the active layer MQW may move to the blue wavelength band. For example, the indium content of the active layer MQW of a light emitting element LE which emits third light (light in the blue wavelength band) may be about 10 to 20 wt %.

The second semiconductor layer SEM2 may be disposed on the active layer MQW. The second semiconductor layer SEM2 may be made of a semiconductor material layer, for example, gallium nitride (GaN) doped with a second conductivity type dopant such as silicon (Si), germanium (Ge), and/or tin (Sn).

An electron blocking layer may be disposed between the first semiconductor layer SEM1 and the active layer MQW. The electron blocking layer may be a layer for suppressing or preventing too many electrons from flowing into the active layer MQW. For example, the electron blocking layer may be AlGaN and/or p-AlGaN doped with p-type Mg. The electron blocking layer can be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be made of InGaN and/or GaN. The superlattice layer can be omitted.

The protective layer INS may be disposed on side surfaces (e.g., outer peripheral surfaces) of the first semiconductor layer SEM1, side surfaces (e.g., outer peripheral surfaces) of the active layer MQW, and side surfaces (e.g., outer peripheral surfaces) of the second semiconductor layer SEM2. The protective layer INS may be a layer for protecting side surfaces (e.g., outer peripheral surfaces) of a light emitting element LE. The protective layer INS may be made of an inorganic layer, for example, silicon nitride (SiNₓ), silicon oxynitride (SiON), silicon oxide (SiOₓ), titanium oxide (TiOₓ), and/or aluminum oxide (AlOₓ).

The contact electrodes CTE may be disposed on the protective layer INS. The contact electrodes CTE may be disposed between the first organic layer 210 and the protective layer INS. The contact electrodes CTE may contact the first organic layer 210.

Although the contact electrodes CTE of each of the light emitting elements LE are disposed on the first organic layer 210 in FIGS. 6 and 7, the present disclosure is not limited thereto. For example, the first organic layer 210 may be disposed on a lower surface and a portion of a side surface of each contact electrode CTE of each of the light emitting elements LE. Alternatively, the first organic layer 210 may be disposed on side surfaces of the conductive layer E1 of each of the light emitting elements LE. Alternatively, the first organic layer 210 may be disposed on the side surfaces of the first semiconductor layer SEM1, the side surfaces of the active layer MQW, and the side surfaces of the second semiconductor layer SEM2 of each of the light emitting elements LE. In this case, the first organic layer 210 may be disposed on a portion of each side surface of the second semiconductor layer SEM2.

The contact electrodes CTE may be connected to the conductive layer E1 exposed without being covered by the protective layer INS. Accordingly, even if one of the contact electrodes CTE is not connected to the conductive layer E1 due to a process error, the other contact electrode CTE may be connected to the conductive layer E1, thereby preventing a light emitting element LE from being not lighted up.

When the contact electrodes CTE are made of a metal with high reflectivity, light travelling in a lateral direction of the light emitting element LE from among light emitted from the active layer MQW of the light emitting element LE may be reflected by the contact electrodes CTE to exit from an upper surface of the light emitting element LE. Accordingly, a loss of light of the light emitting element LE can be reduced, and thus the light emission efficiency of the light emitting element LE can be increased. Therefore, in order to increase the light emission efficiency of the light emitting element LE, the contact electrodes CTE may cover most of side surfaces (e.g., outer peripheral surfaces) of the semiconductor stack STC.

The contact electrodes CTE may include molybdenum (Mo), aluminum (Al), chromium (Cr), gold (Au), titanium (Ti), nickel (Ni), neodymium (Nd), and/or copper (Cu). Specifically, to increase reflectivity, the contact electrodes CTE may have a two-layer structure of chromium (Cr) and gold (Au), a three-layer structure of titanium (Ti), aluminum (Al) and titanium (Ti), or a three-layer structure of indium tin oxide (ITO), silver (Ag) and indium tin oxide (ITO).

Connection electrodes BE connect the contact electrodes CTE of each light emitting element LE to one of the pixel electrodes PXE1 through PXE3. The connection electrodes BE may be connected to one of the pixel electrodes PXE1 through PXE3 through connection holes BH penetrating the first organic layer 210. In addition, the connection electrodes BE may be disposed on an upper surface of the first organic layer 210 and the side surfaces of the contact electrodes CTE. In addition, the connection electrodes BE may be disposed on a portion of the side surfaces of each light emitting element LE. For example, the connection electrodes BE may be disposed on a portion of the protective layer INS of each light emitting element LE.

The connection electrodes BE may include molybdenum (Mo), aluminum (Al), chromium (Cr), gold (Au), titanium (Ti), nickel (Ni), neodymium (Nd), and/or copper (Cu). Alternatively, the connection electrodes BE may be made of a transparent conductive material (TCO) that can transmit light, such as indium tin oxide (ITO) and/or indium zinc oxide (IZO).

When the connection electrodes BE are made of a metal material with high reflectivity such as aluminum (Al), light travelling in the lateral direction of a light emitting element LE from among light emitted from the active layer MQW of the light emitting element LE may be reflected by the connection electrodes BE toward the top of the light emitting element LE. Accordingly, a loss of light of the light emitting element LE can be reduced, and thus the light emission efficiency of the light emitting element LE can be increased.

A third organic layer 211 may partially cover the side surfaces of the light emitting elements LE. In addition, the third organic layer 211 may cover the connection electrodes BE, but at least a portion of each of the connection electrodes BE may be exposed without being covered by the third organic layer 211.

A fourth organic layer 212 may be disposed on the third organic layer 211. The fourth organic layer 212 may partially cover the side surfaces of each of the light emitting elements LE. The fourth organic layer 212 may be disposed on at least a portion of each of the connection electrodes BE exposed without being covered by the third organic layer 211. The upper surface of each of the light emitting elements LE may be exposed without being covered by the fourth organic layer 212.

The third organic layer 211 and the fourth organic layer 212 may be made of an organic layer such as acryl resin, epoxy resin, phenolic resin, polyamide resin, and/or polyimide resin.

The third organic layer 211 and the fourth organic layer 212 are layers for flattening steps caused by the light emitting elements LE. If the third organic layer 211 is high enough to cover most of the side surfaces of each of the light emitting elements LE, the fourth organic layer 212 may be omitted.

The common electrode CE may be disposed on the upper surface of each of the light emitting elements LE and an upper surface of the fourth organic layer 212. The common electrode CE may be a common layer commonly formed in a first subpixel SPX1, a second subpixel SPX2, and a third subpixel SPX3. The common electrode CE may be made of a transparent conductive material (TCO) that can transmit light, such as indium tin oxide (ITO) and/or indium zinc oxide (IZO).

The pixel electrodes PXE1 through PXE3 may be referred to as anodes or first electrodes, and the common electrode CE may be referred to as a cathode or a second electrode.

A first capping layer CAP1 may be disposed on the common electrode CE.

A light blocking layer BM (BM1, BM2), a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be disposed or formed in respective areas defined or partitioned by the light blocking layer BM. Therefore, the first light conversion layer QDL1 may be disposed on the first capping layer CAP1 in the first subpixel SPX1, the second light conversion layer QDL2 may be disposed on the first capping layer CAP1 in the second subpixel SPX2, and the light transmission layer TPL may be disposed on the first capping layer CAP1 in the third subpixel SPX3. The light blocking layer BM may overlap the third organic layer 211 and the fourth organic layer 212 in the third direction DR3 and may not overlap the light emitting elements LE.

The first light conversion layer QDL1 may convert a portion of third light (e.g., light in the blue wavelength band) incident from a light emitting element LE into first light (e.g., light in the red wavelength band). The first light conversion layer QDL1 may include a first base resin BRS1 and first wavelength conversion particles WCP1. The first base resin BRS1 may include a light-transmitting organic material. The first wavelength conversion particles WCP1 may convert a portion of the third light (e.g., light in the blue wavelength band) incident from the light emitting element LE into the first light (e.g., light in the red wavelength band).

The second light conversion layer QDL2 may convert a portion of third light (e.g., light in the blue wavelength band) incident from a light emitting element LE into second light (e.g., light in the green wavelength band). The second light conversion layer QDL2 may include a second base resin BRS2 and second wavelength conversion particles WCP2. The second base resin BRS2 may include a light-transmitting organic material. The second wavelength conversion particles WCP2 may convert a portion of the third light (e.g., light in the blue wavelength band) incident from the light emitting element LE into the second light (e.g., light in the green wavelength band).

The light transmission layer TPL may include a light-transmitting organic material.

For example, the first base resin BRS1, the second base resin BRS2, and the light transmission layer TPL may include epoxy resin, acrylic resin, cardo resin, and/or imide resin. The first and second wavelength conversion particles WCP1 and WCP2 may be quantum dots, quantum rods, fluorescent materials, and/or phosphorescent materials.

The light blocking layer BM may include a first light blocking layer BM1 and a second light blocking layer BM2 stacked sequentially. A length of the first light blocking layer BM1 in the first direction DR1 or a length of the first light blocking layer BM1 in the second direction DR2 may be greater than a length of the second light blocking layer BM2 in the first direction DR1 or a length of the second light blocking layer BM2 in the second direction DR2. The first light blocking layer BM1 and the second light blocking layer BM2 may be made of an organic layer such as acryl resin, epoxy resin, phenolic resin, polyamide resin, and/or polyimide resin. The first light blocking layer BM1 and the second light blocking layer BM2 may include a light blocking material to prevent light of a light emitting element LE of one subpixel from travelling to a neighboring subpixel. For example, the first light blocking layer BM1 and the second light blocking layer BM2 may include an inorganic black pigment such as carbon black and/or an organic black pigment.

A second capping layer CAP2 may be disposed on the first capping layer CAP1 and the light blocking layer BM. The second capping layer CAP2 may be disposed on side and upper surfaces of the light blocking layer BM. For example, the second capping layer CAP2 may be disposed on side surfaces of the first light blocking layer BM1 and side and upper surfaces of the second light blocking layer BM2.

A reflective layer RF may be disposed between the light blocking layer BM and the first light conversion layer QDL1, between the light blocking layer BM and the second light conversion layer QDL2, and between the light blocking layer BM and the light transmission layer TPL. The reflective layer RF may be disposed on the second capping layer CAP2 disposed on the side surfaces of the first light blocking layer BM1 and the side surfaces of the second light blocking layer BM2. The reflective layer RF may reflect light travelling in the lateral direction from the first light conversion layer QDL1, the second light conversion layer QDL2, and the light transmission layer TPL.

The reflective layer RF may include a metal material with high reflectivity, such as aluminum (Al). A thickness of the reflective layer RF may be about 0.1 μm.

Alternatively, to serve as distributed Bragg reflectors, the reflective layer RF may include M (M is an integer of 2 or more) pairs of first and second layers having different refractive indices. In this case, M first layers and M second layers may be arranged alternately. The first and second layers may be made of an inorganic layer, for example, silicon nitride (SiNₓ), silicon oxynitride (SiON), silicon oxide (SiOₓ), titanium oxide (TiOₓ), and/or aluminum oxide (AlOₓ).

A third capping layer CAP3 may be disposed on the second capping layer CAP2, reflective layer RF, the first light conversion layer QDL1, the second light conversion layer QDL2, and the light transmission layer TPL.

The first capping layer CAP1, the second capping layer CAP2, and the third capping layer CAP3 may be made of an inorganic layer, for example, silicon nitride (SiNₓ), silicon oxynitride (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the first capping layer CAP1, the second capping layer CAP2, and the third capping layer CAP3.

A fifth organic layer 213 may be disposed on the third capping layer CAP3. A plurality of color filters CF1 through CF3 may be disposed on the fifth organic layer 213. The color filters CF1 through CF3 may include first color filters CF1, second color filters CF2, and third color filters CF3.

A first color filter CF1 disposed in the first subpixel SPX1 may transmit first light (e.g., light in the red wavelength band) and absorb or block third light (e.g., light in the blue wavelength band). Therefore, the first color filter CF1 may transmit the first light (e.g., light in the red wavelength band) into which a portion of the third light (e.g., light in the blue wavelength band) emitted from a light emitting element LE has been converted by the first light conversion layer QDL1 and may absorb or block the third light (e.g., light in the blue wavelength band) which has not been converted by the first light conversion layer QDL1. Accordingly, the first subpixel SPX1 may output the first light (e.g., light in the red wavelength band).

A second color filter CF2 disposed in the second subpixel SPX2 may transmit second light (e.g., light in the green wavelength band) and absorb or block third light (e.g., light in the blue wavelength band). Therefore, the second color filter CF2 may transmit the second light (e.g., light in the green wavelength band) into which a portion of the third light (e.g., light in the blue wavelength band) emitted from a light emitting element LE has been converted by the second light conversion layer QDL2 and may absorb or block the third light (e.g., light in the blue wavelength band) which has not been converted by the second light conversion layer QDL2. Accordingly, the second subpixel SPX2 may output the second light (e.g., light in the green wavelength band).

A third color filter CF3 disposed in the third subpixel SPX3 may transmit third light (e.g., light in the blue wavelength band). Therefore, the third color filter CF3 may transmit the third light (e.g., light in the blue wavelength band) that passes through the light transmission layer TPL after being emitted from a light emitting element LE. Accordingly, the third subpixel SPX3 may emit the third light (light in the blue wavelength band).

The first color filter CF1, the second color filter CF2, and the third color filter CF3 overlapping each other in the third direction DR3 may overlap the light blocking layer BM in the third direction DR3.

A sixth organic layer 214 for planarization may be disposed on the color filters CF1 through CF3.

The fifth organic layer 213 and the sixth organic layer 214 may be made of acryl resin, epoxy resin, phenolic resin, polyamide resin, and/or polyimide resin.

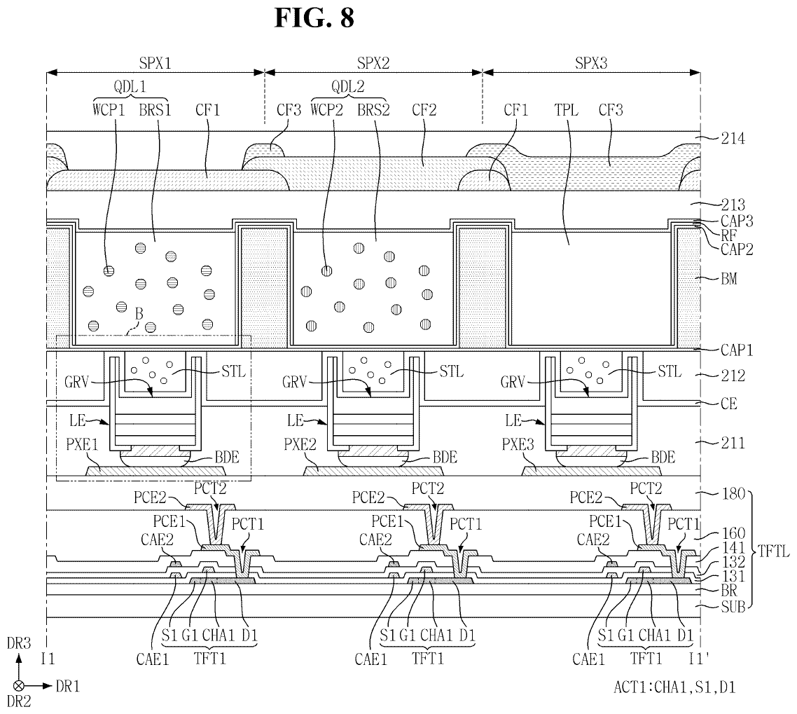

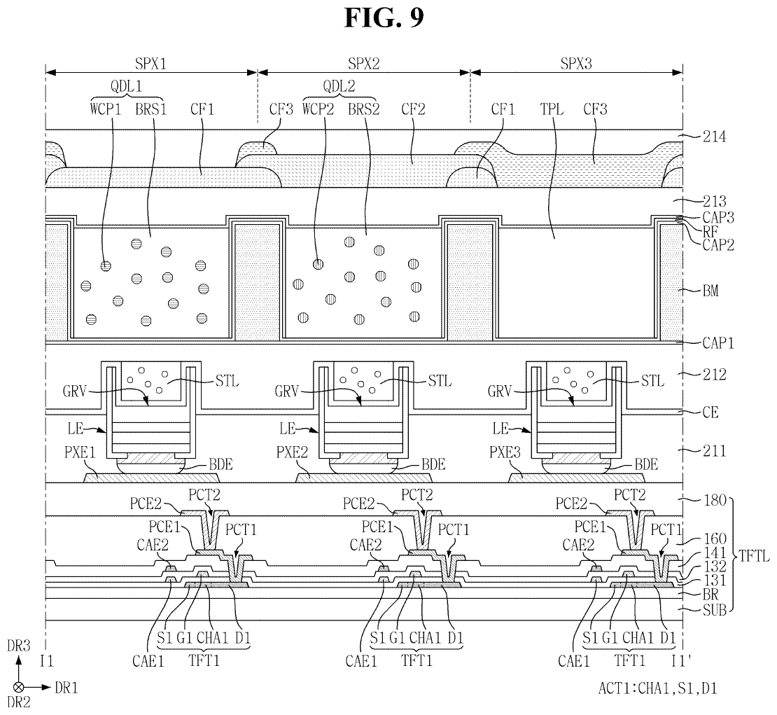

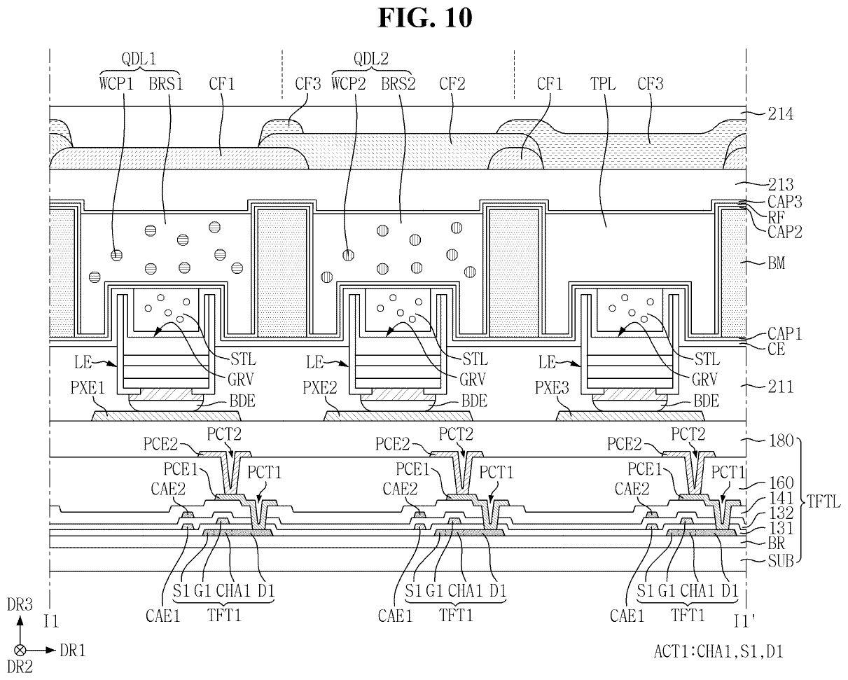

FIG. 8 is a cross-sectional view illustrating an example of a cross section of a display panel 100 corresponding to the line I1-I1′ of FIG. 5. FIG. 9 is a cross-sectional view illustrating an example of a cross section of a display panel 100 corresponding to the line I1-I1′ of FIG. 5. FIG. 10 is a cross-sectional view illustrating an example of a cross section of a display panel 100 corresponding to the line I1-I1′ of FIG. 5.

FIGS. 8 through 10 show embodiments different from the embodiment of FIG. 6 in relation to a light emitting element layer including light emitting elements LE. In addition, FIGS. 8 through 10 show different embodiments in relation to a fourth organic layer 212. In the description of the following embodiments, descriptions overlapping those of the previously described embodiments will be omitted.

Referring to FIGS. 8 through 10, the light emitting elements LE may be disposed on pixel electrodes PXE1 through PXE3. The display panels 100 according to the embodiments of FIGS. 8 through 10 may not include the first organic layer 210 and the connection electrodes BE of FIG. 6.

In one or more embodiments, the light emitting elements LE may include bonding electrodes BDE, respectively. The light emitting elements LE may be placed or bonded on the pixel electrodes PXE1 through PXE3 (or bonding pads connected to the pixel electrodes PXE1 through PXE3) by the bonding electrodes BDE. For example, the light emitting elements LE can be stably placed or bonded on the pixel electrodes PXE1 through PXE3 using a bonding method such as eutectic bonding. In one or more embodiments, each of the pixel electrodes PXE1 through PXE3 may be a multilayer including metal, but the present disclosure is not limited thereto. The type or structure of the light emitting elements LE or the connection structure or method of the light emitting elements LE and the pixel electrodes PXE1 through PXE3 may vary according to embodiments.

Each of the light emitting elements LE may include a groove GRV in a portion including an upper surface. For example, each of the light emitting elements LE may include a groove GRV recessed to a certain depth or more from the upper surface.

In addition, each subpixel SPX may include a light scattering layer STL that fills the groove GRV. For example, the light scattering layer STL may be disposed on a common electrode CE disposed on a light emitting element LE and may fill the inside and/or top of the groove GRV formed in the light emitting element LE (or a groove formed on the light emitting element LE and the common electrode CE by the groove GRV of the light emitting element LE). In one or more embodiments, the light scattering layer STL may completely fill the groove GRV of the light emitting element LE, but the present disclosure is not limited thereto.

FIGS. 8 through 10 show embodiments in which the groove GRV is formed in each of the light emitting elements LE disposed in a first subpixel SPX1, a second subpixel SPX2, and a third subpixel SPX3. However, the present disclosure is not limited thereto. For example, in one or more embodiments, only some of the first subpixel SPX1, the second subpixel SPX2, and the third subpixel SPX3 may include a light emitting element LE including the groove GRV and the light scattering layer STL that fills the groove GRV. For example, a subpixel SPX whose light output efficiency needs to be improved may be selected from among the first subpixel SPX1, the second subpixel SPX2 and the third subpixel SPX3, and the light scattering layer STL may be disposed or formed in the selected subpixel SPX.

The common electrode CE may be disposed on the light emitting elements LE and a third organic layer 211. The common electrode CE may have a shape corresponding to the groove GRV of each of the light emitting elements LE (e.g., a surface profile corresponding to the groove GRV). For example, the common electrode CE may have a uniform thickness overall and may be formed as a thin layer with a surface profile corresponding to a surface shape of an element located thereunder.

A portion of the common electrode CE may be disposed inside the groove GRV of each of the light emitting elements LE. In the groove GRV of each of the light emitting elements LE, the common electrode CE may be located at a lower height than a portion covering an outer portion of the light emitting element LE (e.g., a portion around (e.g., surrounding) the groove GRV). For example, a portion of the common electrode CE, which is disposed on the bottom surface of the groove GRV, may be located at a lower height than another portion of the common electrode CE which is disposed on sidewalls of the groove GRV.

The third organic layer 211 may cover side surfaces (e.g., outer peripheral surfaces) of the light emitting elements LE. In one or more embodiments, the third organic layer 211 may be formed to have a lower height than the light emitting elements LE and may partially cover the side surfaces of the light emitting elements LE. In this case, a portion of the common electrode CE which is disposed on the third organic layer 211 may be located at a lower height than another portion of the common electrode CE which is disposed on the sidewalls of the grooves GRV. For example, the common electrode CE may be located at different heights in different portions according to the shape and/or height of each of the light emitting elements LE and the third organic layer 211.

The height of the third organic layer 211 may vary according to embodiments. For example, in one or more embodiments, the third organic layer 211 may be formed to have a height substantially equal or similar to that of the light emitting elements LE and may entirely cover the side surfaces (e.g., outer peripheral surfaces) of the light emitting elements LE.

In one or more embodiments, the third organic layer 211 may be formed to a height or thickness sufficient to stably form the common electrode CE. For example, the third organic layer 211 may be formed to a height or thickness that can alleviate a step difference of the common electrode CE. Accordingly, the common electrode CE can be prevented from being broken.

In one or more embodiments, a display panel 100 may include the fourth organic layer 212 disposed on the common electrode CE, as illustrated in FIGS. 8 and 9. The fourth organic layer 212 may alleviate a step difference of the light emitting element layer caused by the light emitting elements LE and planarize an upper surface of the light emitting element layer. For example, the fourth organic layer 212 may be formed to have a height substantially equal or similar to the height of the light emitting elements LE as illustrated in FIG. 8 or may be formed to have a height substantially greater than the height of the light emitting elements LE as illustrated in FIG. 9 to entirely cover the light emitting elements LE, the common electrode CE, and the light scattering layers STL.

In one or more embodiments, when the fourth organic layer 212 is formed to have a height greater than a height of the light scattering layers STL as illustrated in FIG. 9, the display panel 100 may include an additional capping layer that covers the light scattering layers STL. For example, the display panel 100 may further include a capping layer that covers the light scattering layers STL and the common electrode CE, and the fourth organic layer 212 may be disposed on the capping layer.

Alternatively, the display panel 100 may not include the fourth organic layer 212 as illustrated in FIG. 10. For example, the fourth organic layer 212 may not be disposed on the common electrode CE, and a light blocking layer BM may be directly disposed on a first capping layer CAP1 covering the common electrode CE and the light scattering layers STL. In one or more embodiments, at least a portion of each of the light emitting elements LE and the light scattering layers STL may be disposed at a higher height than the third organic layer 211 and may be surrounded by a first light conversion layer QDL1, a second light conversion layer QDL2, or a light transmission layer TPL. For example, the light emitting elements LE, the common electrode CE, the light scattering layers STL, and the first capping layer CAP1 may protrude above the third organic layer 211.

The first light conversion layer QDL1, the second light conversion layer QDL2, the light transmission layer TPL, and the light blocking layer BM may be disposed on the light emitting element layer including the light emitting elements LE, the common electrode CE, and the light scattering layers STL.

The light blocking layer BM may be disposed between emission areas of the subpixels SPX and/or around the emission areas. The light blocking layer BM may be around (e.g., may surround) the first light conversion layer QDL1, the second light conversion layer QDL2, and the light transmission layer TPL.

The first light conversion layer QDL1, the second light conversion layer QDL2, and the light transmission layer TPL may be disposed in the emission areas of the subpixels SPX defined by the light blocking layer BM. For example, the first light conversion layer QDL1, the second light conversion layer QDL2, and the light transmission layer TPL may be disposed in an emission area of the first subpixel SPX1, an emission area of the second subpixel SPX2, and an emission area of the third subpixel SPX3, respectively. The first light conversion layer QDL1, the second light conversion layer QDL2, and the light transmission layer TPL may be covered with a third capping layer CAP3.

In one or more embodiments, a height of the light blocking layer BM may be substantially equal or similar to a height of each of the first light conversion layer QDL1, the second light conversion layer QDL2, and the light transmission layer TPL. However, the present disclosure is not limited thereto. For example, the light blocking layer BM may also be formed to have a height greater than the highest height of each of the first light conversion layer QDL1, the second light conversion layer QDL2, and the light transmission layer TPL. Alternatively, at least a portion of each of the first light conversion layer QDL1, the second light conversion layer QDL2, and the light transmission layer TPL may be formed to have a height greater than the height of the light blocking layer BM.

The light blocking layer BM may be a single layer or a multilayer. For example, the light blocking layer BM may be a single layer or may be a multilayer including a first light blocking layer BM1 and a second light blocking layer BM2 as in the embodiment of FIG. 6.

The light blocking layer BM may include vertical side surfaces or may include inclined side surfaces as in the embodiment of FIG. 6. The shape, height, and/or structure of the light blocking layer BM may vary according to embodiments.

In one or more embodiments, the display panel 100 may further include a reflective layer RF disposed on the light blocking layer BM. For example, the reflective layer RF and the third capping layer CAP3 may be sequentially disposed on a second capping layer CAP2 covering the light blocking layer BM. The reflective layer RF may cover at least the side surfaces of the light blocking layer BM. For example, the reflective layer RF may cover the side and upper surfaces of the light blocking layer BM. The reflective layer RF may increase the amount of light emitted from the subpixels SPX and improve the light efficiency of the subpixels SPX.

A fifth organic layer 213, color filters CF1 through CF3, and a sixth organic layer 214 may be disposed on the third capping layer CAP3.

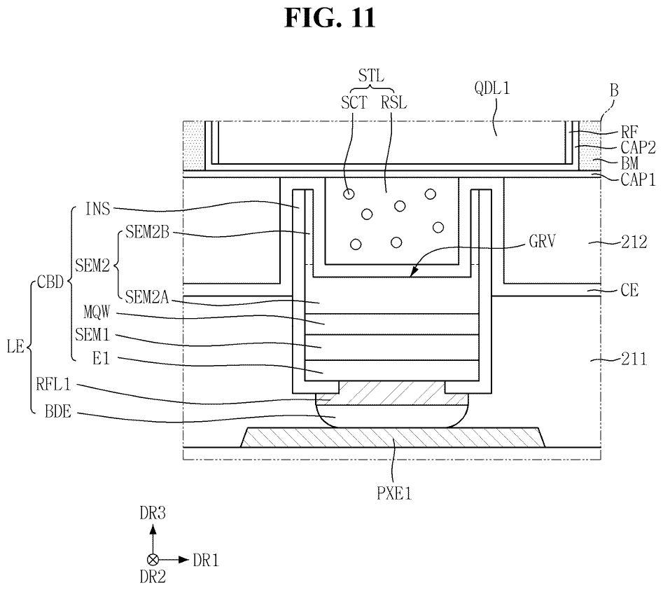

FIG. 11 is a detailed cross-sectional view of an example of an area B of FIG. 8. For example, FIG. 11 shows a light emitting element LE including a groove GRV and a light scattering layer STL filling the groove GRV.

Referring to FIG. 11, the light emitting element LE may include a body portion CBD (e.g., an LED chip body) and a bonding electrode BDE. In one or more embodiments, the light emitting element LE may further include a first reflective layer RFL1 disposed between the body portion CBD and the bonding electrode BDE. The first reflective layer RFL1 may be disposed under the body portion CBD.

The body portion CBD may include a first semiconductor layer SEM1, an active layer MQW, and a second semiconductor layer SEM2 disposed sequentially along a direction (e.g., the third direction DR3). For example, the first semiconductor layer SEM1, the active layer MQW, and the second semiconductor layer SEM2 may be sequentially disposed on a pixel electrode. In one or more embodiments, the body portion CBD may further include a conductive layer E1 disposed on a surface (e.g., a lower surface) of the first semiconductor layer SEM1 and a protective layer INS covering side surfaces (e.g., outer peripheral surfaces) of the conductive layer E1, the first semiconductor layer SEM1, the active layer MQW, and the second semiconductor layer SEM2.

In one or more embodiments, the conductive layer E1 may have a shape and/or size corresponding to those of the first semiconductor layer SEM1, the active layer MQW, and the second semiconductor layer SEM2. For example, the conductive layer E1 may be etched together with semiconductor layers for manufacturing light emitting elements LE on a semiconductor substrate on which the semiconductor layers are grown. The etched semiconductor layers may include the first semiconductor layer SEM1, the active layer MQW, and the second semiconductor layer SEM2 of each of the light emitting elements LE, and the conductive layer E1 may be disposed on the first semiconductor layer SEM1, the active layer MQW, and the second semiconductor layer SEM2. The shape or size of the conductive layer E1 may vary according to embodiments. The conductive layer E1 may include molybdenum (Mo), aluminum (Al), chromium (Cr), gold (Au), titanium (Ti), nickel (Ni), neodymium (Nd), and/or copper (Cu). Alternatively, the conductive layer E1 may include a transparent conductive material such as metal oxide.

In one or more embodiments, the protective layer INS may further cover the conductive layer E1. For example, the protective layer INS may cover the side surfaces (e.g., outer peripheral surfaces) of the conductive layer E1, the first semiconductor layer SEM1, the active layer MQW, and the second semiconductor layer SEM2.

In one or more embodiments, the protective layer INS may partially cover a lower surface of the conductive layer E1. For example, the protective layer INS may cover an edge portion of the lower surface of the conductive layer E1 and may include an opening exposing a central portion of the conductive layer E1. However, the present disclosure is not limited thereto. For example, the protective layer INS may cover only the side surfaces of the conductive layer E1 or may not cover the conductive layer E1.

In one or more embodiments, the body portion CBD may have a quadrangular cross-sectional shape such as a square, rectangular, or trapezoidal shape. For example, the body portion CBD may be a vertical micro-LED chip having a square or rectangular cross-sectional shape. Alternatively, the body portion CBD may have a reverse-tapered (or tapered) trapezoidal cross-sectional shape as in the embodiment of FIG. 7. The type, shape, and/or size of the body portion CBD may vary according to embodiments.

The bonding electrode BDE may include a conductive material (e.g., a bonding metal) suitable for bonding. In one or more embodiments, the bonding electrode BDE may be disposed on a lower surface of the first reflective layer RFL1 and may be electrically connected to the conductive layer E1 through the first reflective layer RFL1. The bonding electrode BDE may be bonded onto a pixel electrode (e.g., a first pixel electrode PXE1, a second pixel electrode PXE2, and/or a third pixel electrode PXE3) and electrically connected to the pixel electrode.

The first reflective layer RFL1 may be disposed on a lower surface of the body portion CBD. The first reflective layer RFL1 may include a metal with high light reflectivity. For example, the first reflective layer RFL1 may be composed of at least one metal layer including at least one of metals with high reflectivity, such as aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir) and/or chromium (Cr), and/or another reflective material. In one or more embodiments, the first reflective layer RFL1 may be a multilayer composed of a reflective metal layer and a conductive bonding layer disposed on at least one surface of the reflective metal layer, but the present disclosure is not limited thereto.

Light generated in the light emitting element LE and travelling toward the bottom of the body portion CBD may be reflected by the first reflective layer RFL1 toward the top of the light emitting element LE. For example, a light output surface through which light is emitted from the light emitting element LE may include an upper surface of the light emitting element LE (e.g., an upper surface of the second semiconductor layer SEM2). At least a portion of the light reflected by the first reflective layer RFL1 may pass through the upper surface of the light emitting element LE and enter a first light conversion layer QDL1, a second light conversion layer QDL2, and/or a light transmission layer TPL. Accordingly, the light output efficiency of the light emitting element LE can be increased.

The light emitting element LE may include the groove GRV formed in its upper surface. The groove GRV may be formed in the second semiconductor layer SEM2 of the light emitting element LE. For example, the groove GRV may be formed by etching a portion of the second semiconductor layer SEM2. Accordingly, the light emitting element LE may include the groove GRV in a portion where the second semiconductor layer SEM2 is disposed.

In an embodiment, the groove GRV may be surrounded by the second semiconductor layer SEM2. For example, a bottom surface and sidewalls (e.g., an inner surface) of the groove GRV may be defined by a surface of the second semiconductor layer SEM2 (e.g., an etched surface of the second semiconductor layer SEM2) exposed as the second semiconductor layer SEM2 is etched.

In one or more embodiments, the second semiconductor layer SEM2 may include a second conductivity type dopant (e.g., an n-type dopant) such as Si and may include at least two portions having different doping concentrations (e.g., different doping concentrations of the second conductivity type dopant). For example, the second semiconductor layer SEM2 may include a first portion SEM2A doped with the second conductivity type dopant at a first concentration and a second portion SEM2B doped with the second conductivity type dopant at a second concentration lower than the first concentration. For example, the second semiconductor layer SEM2 may include at least one high-doped layer including the first portion SEM2A and at least one low-doped layer disposed on the high-doped layer and including the second portion SEM2B.

The groove GRV may be disposed at a lower height than the first portion SEM2A of the second semiconductor layer SEM2. For example, the groove GRV may be formed by etching the second semiconductor layer SEM2 to a depth that can stably expose the first portion SEM2A of the second semiconductor layer SEM2. For example, the bottom surface of the groove GRV may be disposed at a height lower than a highest height of the first portion SEM2A of the second semiconductor layer SEM2.

In one or more embodiments, the first portion SEM2A of the second semiconductor layer SEM2 may include the bottom surface of the groove GRV. For example, an upper surface of the first portion SEM2A may form the bottom surface of the groove GRV. In one or more embodiments, the first portion SEM2A may further include a portion of each sidewall of the groove GRV. For example, the first portion SEM2A may include a lower portion of each sidewall of the groove GRV which is close to the bottom surface of the groove GRV.

In one or more embodiments, the second portion SEM2B of the second semiconductor layer SEM2 may include a portion of each sidewall of the groove GRV. For example, most of the second portion SEM2B of the second semiconductor layer SEM2 may be removed during the process of forming the groove GRV, and only an edge portion adjacent to the protective layer INS may remain to define a portion of each sidewall of the groove GRV (e.g., a portion including an upper portion).

A common electrode CE may contact the first portion SEM2A of the second semiconductor layer SEM2 inside and/or on the groove GRV. Because the common electrode CE is directly disposed on the first portion SEM2A corresponding to the high-doped layer of the second semiconductor layer SEM2, ohmic formation (e.g., ohmic contact) between the light emitting element LE and the common electrode CE can be improved. Accordingly, the electrical connection between the light emitting element LE and the common electrode CE can be improved, and the contact resistance between them can be lowered. Therefore, according to one or more embodiments, it is possible to reduce fluctuations or drops in the driving voltage of the display device 10 (e.g., in the second power supply voltage VSS applied to the display panel 100) and possible to improve power consumption by reducing or optimizing the driving voltage range of the display device 10.

The upper surface of the light emitting element LE including the groove GRV may be covered with the common electrode CE. The common electrode CE may be formed to have a thickness smaller than the depth of the groove GRV and may not substantially fill the groove GRV. For example, even if the common electrode CE is formed on the light emitting element LE, the groove GRV (e.g., a space corresponding to the groove GRV) may still remain on the light emitting element LE. The groove GRV may be filled with the light scattering layer STL.

The light scattering layer STL may fill at least a portion of the groove GRV. For example, the light scattering layer STL may be formed to have a thickness or height corresponding to the depth of the groove GRV so as to substantially completely fill the groove GRV. However, the present disclosure is not limited thereto. For example, the light scattering layer STL may also be formed to have a thickness or height smaller than the depth of the groove GRV and may fill only a portion of the groove GRV.

The light scattering layer STL may include light scatterers SCT (or a light diffusing agent). For example, the light scattering layer STL may include a base resin RSL and the light scatterers SCT dispersed in the base resin RSL. The base resin RSL may include a light-transmitting material including epoxy resin, acrylic resin, cardo resin, and/or imide resin. The light scatterers SCT may include titanium dioxide (TiO₂) and/or silicon dioxide (SiO₂). Because the light scattering layer STL is disposed inside and/or on the groove GRV formed on the upper surface of the light emitting element LE, the light output efficiency of the light emitting element LE can be increased.

In addition, because the groove GRV is formed on the upper surface of the light emitting element LE, a distance between the active layer MQW of the light emitting element LE and the light output surface (e.g., the upper surface of the light emitting element LE which includes the bottom surface of the groove GRV) can be reduced. Accordingly, the light output efficiency of the light emitting element LE can be further increased.

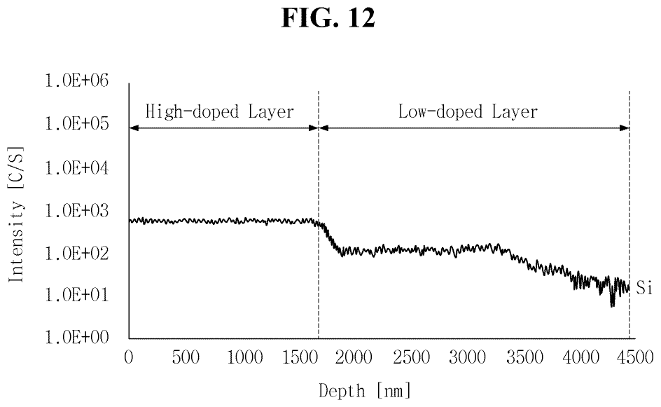

FIG. 12 is a graph illustrating the carrier doping concentration of a second semiconductor layer SEM2 according to one or more embodiments. For example, FIG. 12 shows Si doping concentration with respect to the depth of the second semiconductor layer SEM2 (or the distance from an active layer MQW).

In FIG. 12, depth, which is an independent variable on the horizontal axis, represents the depth (or height) of the second semiconductor layer SEM2 based on the active layer MQW. For example, the depth of the second semiconductor layer SEM2 illustrated in the graph of FIG. 12 may correspond to the distance of the second semiconductor layer SEM2 at a specific position from the active layer MQW (or the height from the active layer MQW). A numerical unit of the horizontal axis may be nanometers [nm]. A dependent variable on the vertical axis represents carrier concentration (e.g., Si doping concentration). A numerical unit of the vertical axis may be charge per square area [C/S] (e.g., charge per 1 cm²).

Referring to FIGS. 11 and 12, the second semiconductor layer SEM2 may include a high-doped layer doped with Si at a first concentration (e.g., at a doping concentration higher than 1.0E+02 [C/S]) and a low-doped layer doped with Si at a second concentration lower than the first concentration. In one or more embodiments, the high-doped layer of the second semiconductor layer SEM2 may include a first portion SEM2A of the second semiconductor layer SEM2, and the low-doped layer of the second semiconductor layer SEM2 may include a second portion SEM2B of the second semiconductor layer SEM2.

In one or more embodiments, a total doping concentration of the first portion SEM2A of the second semiconductor layer SEM2 doped with Si at the first concentration may be about 1.0E+18/cm³ to 1.0E+19/cm³ (10¹⁸/cm³ to 10¹⁹/cm³). A total doping concentration of the second portion SEM2B of the second semiconductor layer SEM2 doped with Si at the second concentration may be about 1.0E+16/cm (10¹⁶/cm³). The carrier concentration or doping concentration of each of the first portion SEM2A and the second portion SEM2B of the second semiconductor layer SEM2 may vary according to one or more embodiments. However, the first portion SEM2A of the second semiconductor layer SEM2 may be doped at a higher concentration than the second portion SEM2B and thus may have higher conductivity.

According to one or more embodiments, a groove GRV may be formed in a light emitting element LE to expose the first portion SEM2A corresponding to the high-doped layer of the second semiconductor layer SEM2, and a common electrode CE may be formed on the first portion SEM2A of the second semiconductor layer SEM2. Accordingly, ohmic formation (e.g., ohmic contact) between the light emitting element LE and the common electrode CE can be improved, and the driving voltage and power consumption of a display device 10 can be improved and/or optimized.

For example, when a thickness of the first portion SEM2A of the second semiconductor layer SEM2 is in the range of about 1500 to 2000 nm (1.5 to 2 μm), the groove GRV may be formed in the light emitting element LE to expose the first portion SEM2A of the second semiconductor layer SEM2 at a position spaced (e.g., spaced apart) from the active layer MQW by a distance of about 500 to 1500 nm (0.5 to 1.5 μm), and the common electrode CE may be directly formed on the exposed portion of the second semiconductor layer SEM2. For example, the groove GRV may be formed at a position spaced (e.g., spaced apart) from the active layer MQW by about 500 nm (0.5 μm) or more, and a bottom surface of the groove GRV may be located at a height of about 500 to 1500 nm (0.5 to 1.5 μm) from an upper surface of the active layer MQW.

By forming the groove GRV in the light emitting element LE at a position spaced (e.g., spaced apart) from the active layer MQW by a distance of about 500 nm or more (e.g., a position at a height of 500 nm or more from the active layer MQW), it is possible to secure the structural stability of the light emitting element LE. In addition, by forming the groove GRV in the light emitting element LE at a position spaced (e.g., spaced apart) from the active layer MQW by a distance of about 1500 nm or less, it is possible to appropriately or stably expose the first portion SEM2A of the second semiconductor layer SEM2. However, the height or depth of the groove GRV may vary according to the thickness or height of the first portion SEM2A (or the high-doped layer) of the second semiconductor layer SEM2.

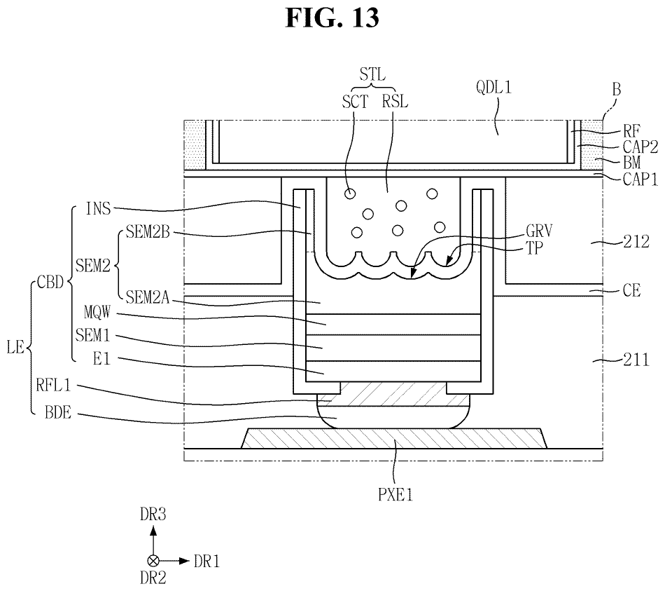

FIG. 13 is a detailed cross-sectional view of an example of the area B of FIG. 8. For example, FIG. 13 shows an embodiment different from the embodiment of FIG. 11 in relation to the shape and/or structure of a groove GRV formed in a light emitting element LE and the resultant shapes and/or structures of a common electrode CE and a light scattering layer STL.

Referring to FIG. 13, a bottom surface of the groove GRV may not be substantially flat. For example, after the groove GRV is formed to expose a first portion SEM2A of a second semiconductor layer SEM2, a texturing process may be additionally performed to give roughness to surfaces of the groove GRV including the bottom surface. Accordingly, a light transmission pattern including a pattern having a lens shape or a textured pattern having another shape may be formed on the bottom surface of the groove GRV.

In one or more embodiments, because the groove GRV includes a light transmission pattern (e.g., a textured pattern) having surface roughness, a light transmission pattern TP having a shape corresponding to the shape of the groove GRV (e.g., a shape corresponding to the shape of the textured pattern of the groove GRV) and/or surface roughness may also be formed in the common electrode CE and the light scattering layer STL. For example, the common electrode CE and the light scattering layer STL may include the light transmission pattern TP disposed on the bottom surface of the groove GRV.

According to the above-described embodiment, the light output efficiency of the light emitting element LE can be improved. For example, it is possible to increase the amount of light generated in the light emitting element LE, passing through the light scattering layer STL, and entering a first light conversion layer QDL1, a second light conversion layer QDL2, and/or a light transmission layer TPL. Accordingly, the light efficiency of the light emitting element LE and a subpixel SPX including the light emitting element LE can be improved.

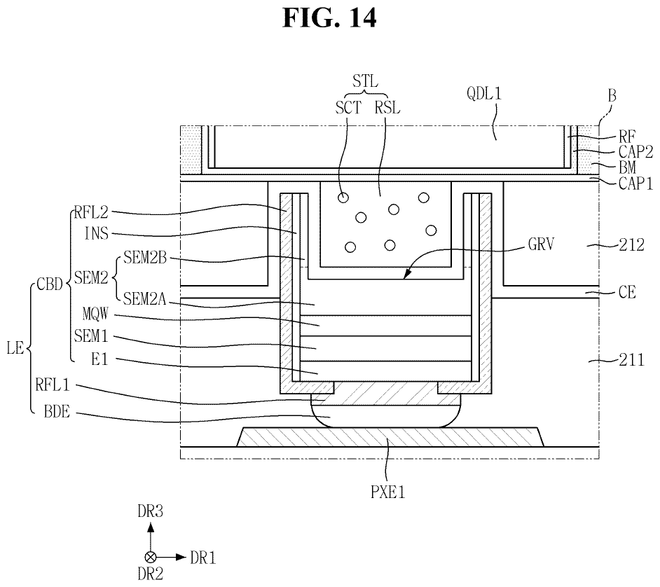

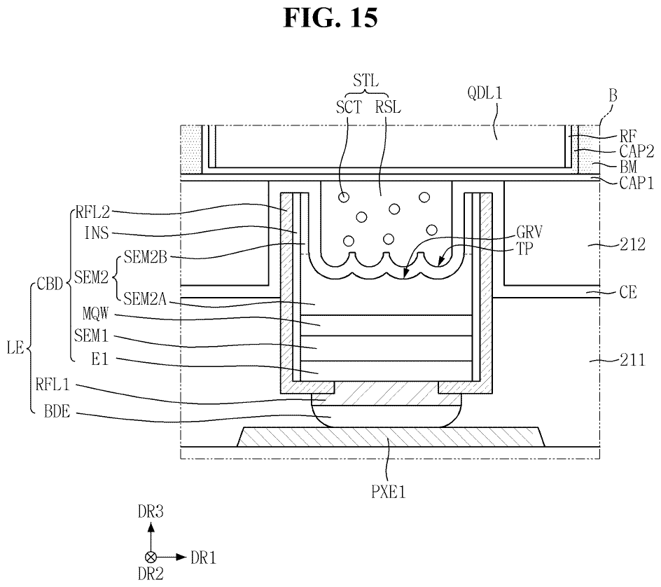

FIG. 14 is a detailed cross-sectional view of an example of the area B of FIG. 8. FIG. 15 is a detailed cross-sectional view of an example of the area B of FIG. 8. The embodiments of FIGS. 14 and 15 are different from the embodiments of FIGS. 11 and 13 in that a light emitting element LE further includes a second reflective layer RFL2.

Referring to FIGS. 14 and 15, the light emitting element LE may further include the second reflective layer RFL2 disposed on its side surfaces (e.g., outer peripheral surfaces). For example, a body portion CBD may further include the second reflective layer RFL2 covering side surfaces (e.g., outer peripheral surfaces) of a conductive layer E1, a first semiconductor layer SEM1, an active layer MQW, and a second semiconductor layer SEM2.

In one or more embodiments, the second reflective layer RFL2 may include distributed Bragg reflectors. For example, the second reflective layer RFL2 may include at least one pair of a first layer (e.g., a low refractive index layer) and a second layer (e.g., a high refractive index layer) disposed sequentially or alternately and having different refractive indices. The second reflective layer RFL2 may reflect light generated in the light emitting element LE and travelling in the lateral direction of the body portion CBD.

In one or more embodiments, the second reflective layer RFL2 may be composed of multiple layers of insulating layers including an insulating material. For example, the second reflective layer RFL2 may include inorganic layers (e.g., inorganic insulating layers made of silicon nitride (SiNₓ), silicon oxynitride (SiON), silicon oxide (SiOₓ), titanium oxide (TiOₓ), and/or aluminum oxide (AlOₓ)).

In one or more embodiments, the body portion CBD may include a protective layer INS covering the side surfaces (e.g., outer peripheral surfaces) of the conductive layer E1, the first semiconductor layer SEM1, the active layer MQW, and the second semiconductor layer SEM2, and the second reflective layer RFL2 may be disposed on an outer surface (e.g., outer peripheral surface) of the protective layer INS. For example, the second reflective layer RFL2 may cover side surfaces (e.g., outer peripheral surfaces) of the protective layer INS. In one or more embodiments, the protective layer INS may not be disposed on a lower surface of the conductive layer E1, but the present disclosure is not limited thereto.

Alternatively, the body portion CBD may not include the protective layer INS. For example, the second reflective layer RFL2 may directly cover the side surfaces (e.g., outer peripheral surfaces) of the conductive layer E1, the first semiconductor layer SEM1, the active layer MQW, and the second semiconductor layer SEM2. In this case, the second reflective layer RFL2 may not only reflect light generated in the light emitting element LE and travelling in the lateral direction of the body portion CBD, but also function as a protective layer that protects the conductive layer E1, the first semiconductor layer SEM1, the active layer MQW, and the second semiconductor layer SEM2.

In one or more embodiments, the second reflective layer RFL2 may partially cover the lower surface of the conductive layer E1. For example, the second reflective layer RFL2 may cover an edge portion of the lower surface of the conductive layer E1 and may include an opening exposing a central portion of the conductive layer E1. On the lower surface of the conductive layer E1, a portion of a first reflective layer RFL1 and a portion of the second reflective layer RFL2 may overlap each other. The lower and side surfaces of the conductive layer E1, the first semiconductor layer SEM1, the active layer MQW, and the second semiconductor layer SEM2 may be covered with the first reflective layer RFL1 and the second reflective layer RFL2.

Light generated in the light emitting element LE and travelling toward the bottom and sides of the body portion CBD may be reflected by the first and second reflective layers RFL1 and RFL2 toward the top of the light emitting element LE. Accordingly, the amount of light emitted to above the light emitting element LE can be further increased, and the light output efficiency of the light emitting element LE and a subpixel SPX including the light emitting element LE can be effectively improved.

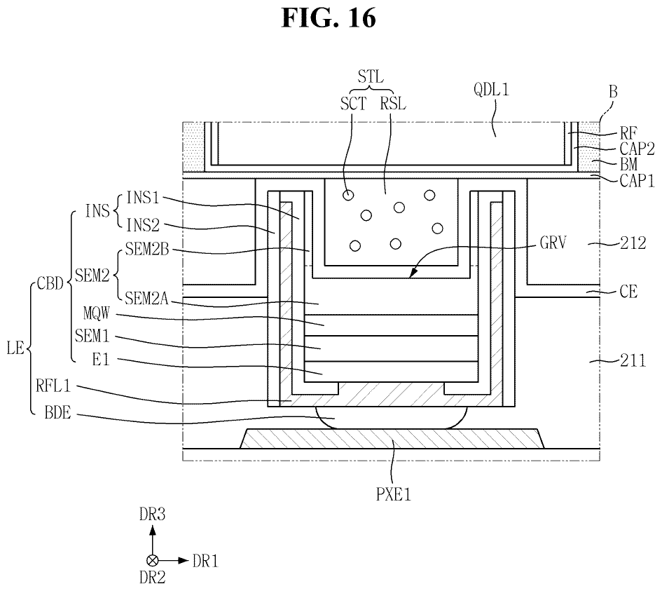

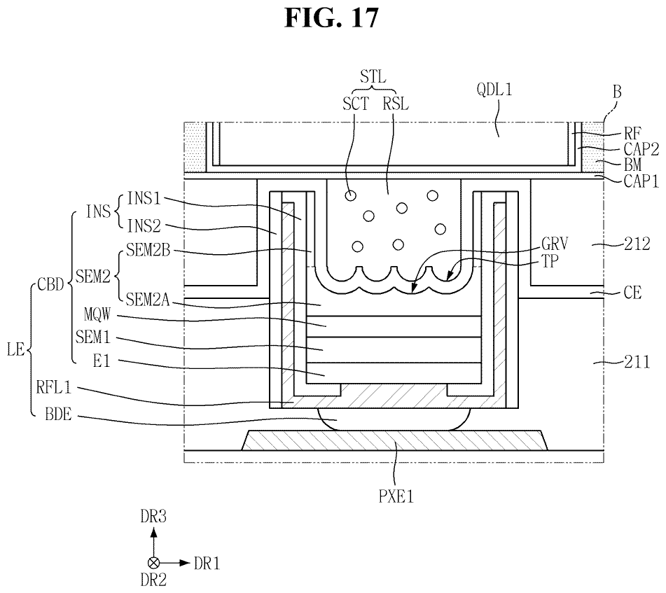

FIG. 16 is a detailed cross-sectional view of an example of the area B of FIG. 8. FIG. 17 is a detailed cross-sectional view of an example of the area B of FIG. 8. For example, FIG. 16 shows an embodiment different from the embodiment of FIG. 11 in relation to a first reflective layer RFL1 and a protective layer INS, and FIG. 17 shows an embodiment different from the embodiment of FIG. 16 in relation to a light transmission pattern TP.

Referring to FIGS. 16 and 17, the first reflective layer RFL1 may be extended to cover side surfaces (e.g., outer peripheral surfaces) of a conductive layer E1, a first semiconductor layer SEM1, an active layer MQW, and a second semiconductor layer SEM2. For example, a portion of the first reflective layer RFL1 may be disposed on a lower surface of the conductive layer E1, and the other portion of the first reflective layer RFL1, which extends from the above portion may be disposed on side surfaces (e.g., outer peripheral surfaces) of the protective layer INS (e.g., a first protective layer INS1). Accordingly, the light output efficiency of a light emitting element LE and a subpixel SPX including the light emitting element LE can be effectively improved without the formation of an additional reflective layer (e.g., the second reflective layer RFL2 of FIGS. 14 and 15).

In one or more embodiments, the first reflective layer RFL1 may include a metal with high light reflectivity and may have conductivity. In this case, side surfaces of the first reflective layer RFL1 may be covered by the protective layer INS to ensure insulation between the first reflective layer RFL1 and a common electrode CE. For example, the protective layer INS may be a multilayer including a first insulating layer INS1, which covers the side surfaces (e.g., outer peripheral surfaces) of the conductive layer E1, the first semiconductor layer SEM1, the active layer MQW, and the second semiconductor layer SEM2, and a second insulating layer INS2, which covers the side surfaces (e.g., outer peripheral surfaces) of the first reflective layer RFL1.

A groove GRV may include a light transmission pattern having surface roughness or may not include a light transmission pattern. For example, as illustrated in FIG. 16, a bottom surface of the groove GRV may be substantially flat. Alternatively, as illustrated in FIG. 17, the bottom surface of the groove GRV may include a light transmission pattern TP having surface roughness. Accordingly, the common electrode CE and a light scattering layer STL may include the light transmission pattern TP having a shape corresponding to the shape of the groove GRV and/or surface roughness.

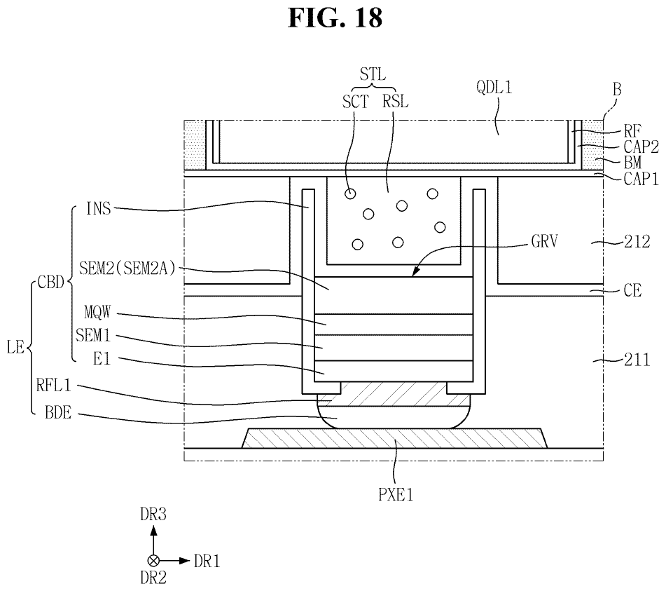

FIG. 18 is a detailed cross-sectional view of an example of the area B of FIG. 8. For example, FIG. 18 shows an embodiment different from the embodiment of FIG. 11 in relation to a second semiconductor layer SEM2.

Referring to FIG. 18, the second semiconductor layer SEM2 may not include a low-doped layer including the second portion SEM2B of FIG. 11 and may include only a first portion SEM2A made of a high-doped layer. For example, in a process of forming a groove GRV by etching the second semiconductor layer SEM2, the second portion SEM2B of the second semiconductor layer SEM2 may be completely etched, and only a protective layer INS may remain in a light emitting element LE at a height above a bottom surface of the groove GRV. For example, a portion of the protective layer INS may protrude above the second semiconductor layer SEM2 and may be around (e.g., may surround) the groove GRV.

In this case, the groove GRV may be defined by the first portion SEM2A of the second semiconductor layer SEM2 and the protective layer INS. For example, a surface of the first portion SEM2A (e.g., an upper surface of the first portion SEM2A) exposed as the second semiconductor layer SEM2 is etched may form the bottom surface of the groove GRV, and a portion of the protective layer INS, which protrudes above the second semiconductor layer SEM2, may define sidewalls of the groove GRV.

Although only a modified embodiment of the embodiment of FIG. 11 is disclosed in FIG. 18, the present disclosure is not limited thereto. For example, at least two of the embodiments disclosed herein may be combined with each other. For example, a second semiconductor layer SEM2 of a light emitting element LE according to at least one of the embodiments of FIGS. 13 through 17 may not include the second portion SEM2B.

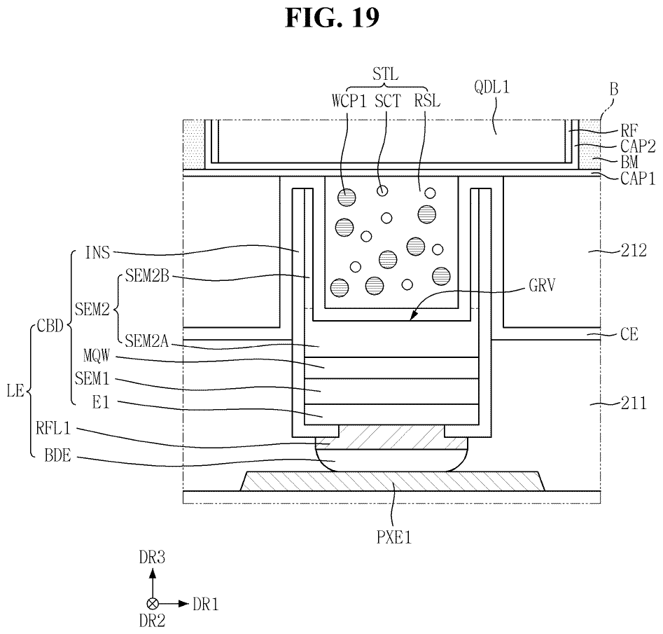

FIG. 19 is a detailed cross-sectional view of an example of the area B of FIG. 8. For example, FIG. 19 shows an embodiment different from the embodiment of FIG. 11 in relation to a light scattering layer STL.

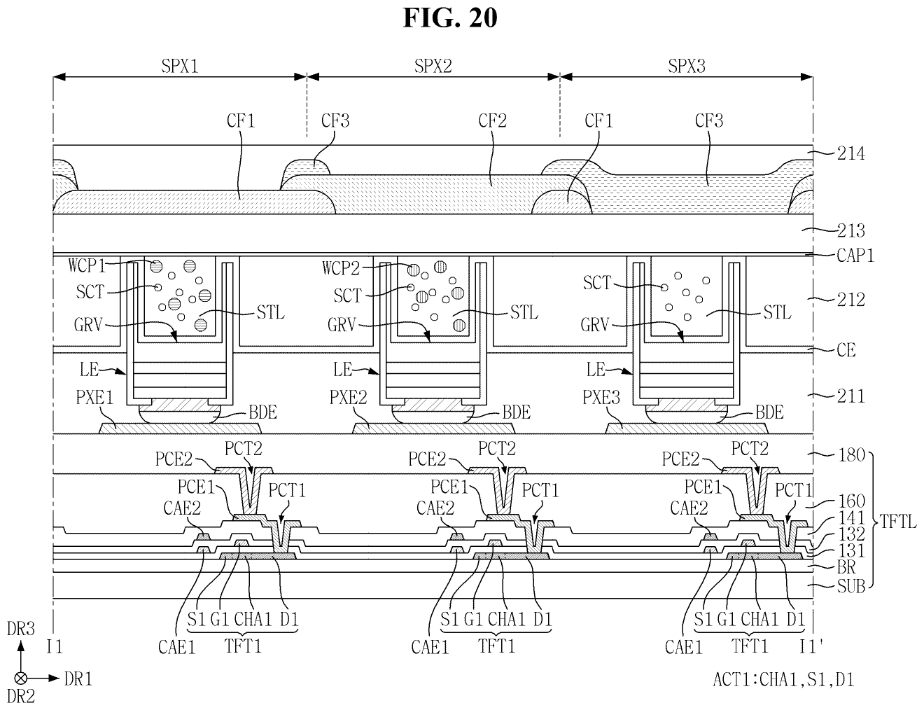

Referring to FIG. 19, the light scattering layer STL may further include wavelength conversion particles. For example, if the color or wavelength of light emitted from a light emitting element LE disposed in an emission area of a subpixel SPX is different from the color or wavelength of light that the subpixel SPX is intended to emit, the light scattering layer STL disposed in the subpixel SPX may further include wavelength conversion particles. For example, a light scattering layer STL of a first subpixel SPX1 may further include first wavelength conversion particles WCP1, and a light scattering layer STL of a second subpixel SPX2 may further include second wavelength conversion particles WCP2 (e.g., see FIG. 20).

In one or more embodiments, a light scattering layer STL of a third subpixel SPX3 may not include wavelength conversion particles. For example, if a light emitting element LE of the third subpixel SPX3 emits light of a color or wavelength (e.g., blue light) that the third subpixel SPX3 is intended to emit, the light scattering layer STL of the third subpixel SPX3 may not include wavelength conversion particles (e.g., see FIG. 20).

In one or more embodiments, in order to increase the light diffusion efficiency and/or light conversion efficiency by the light scattering layer STL, the amount of light scatterers SCT and/or wavelength conversion particles included in the light scattering layer STL may be increased. For example, at least one of the area and/or height of a groove GRV (or a light emitting element LE) may be increased to increase the volume of the light scattering layer STL filling the groove GRV. Accordingly, the amount of light scatterers SCT and/or wavelength conversion particles included in the light scattering layer STL can be increased.

FIG. 20 is a cross-sectional view illustrating an example of a cross section of a display panel 100 corresponding to the line I1-I1′ of FIG. 5. For example, FIG. 20 shows an embodiment of a display panel 100 which includes the pixel electrodes PXE1 through PXE3 and the light emitting elements LE of FIG. 5, but does not include the first light conversion layer QDL1, the second light conversion layer QDL2, and the light transmission layer TPL.

Referring to FIG. 20, a light scattering layer STL of at least one subpixel SPX may include wavelength conversion particles. For example, a light scattering layer STL of a first subpixel SPX1 may include first wavelength conversion particles WCP1, and a light scattering layer STL of a second subpixel SPX2 may include second wavelength conversion particles WCP2.

A light conversion layer may be disposed on a light emitting element layer including the light emitting elements LE and the light scattering layers STL of the subpixels SPX. For example, if appropriate light conversion efficiency can be obtained by the light scattering layers STL of the first subpixel SPX1 and the second subpixel SPX2, a fifth organic layer 213 may be directly formed on a first capping layer CAP1, and color filters CF1 through CF3 and a sixth organic layer 214 may be disposed on the fifth organic layer 213.

Alternatively, even if the light scattering layer STL disposed in at least one subpixel SPX includes wavelength conversion particles as in the embodiments of FIGS. 19 and 20, the first light conversion layer QDL1, the second light conversion layer QDL2, and the light transmission layer TPL may be disposed on the light emitting element layer. For example, the first light conversion layer QDL1, the second light conversion layer QDL2, and/or the light transmission layer TPL may be optionally placed on the light emitting element layer in consideration of the light efficiency and/or color purity of the subpixels SPX.

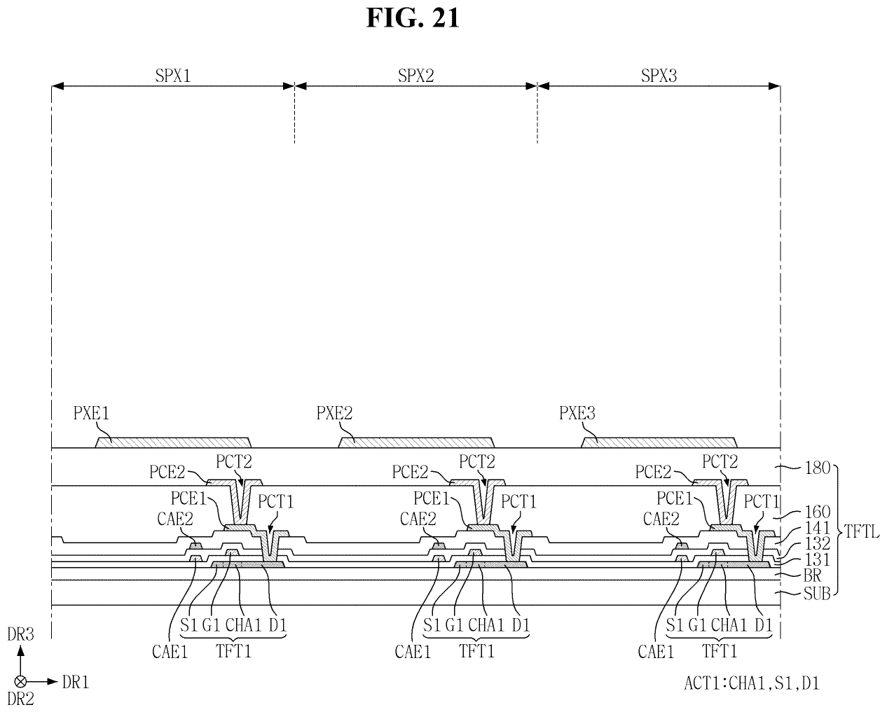

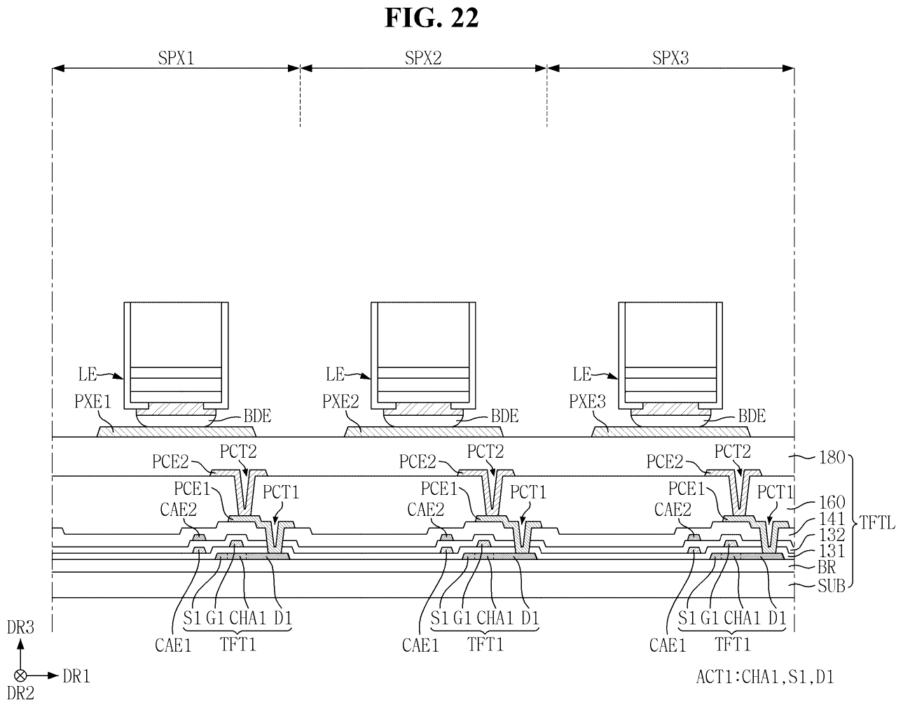

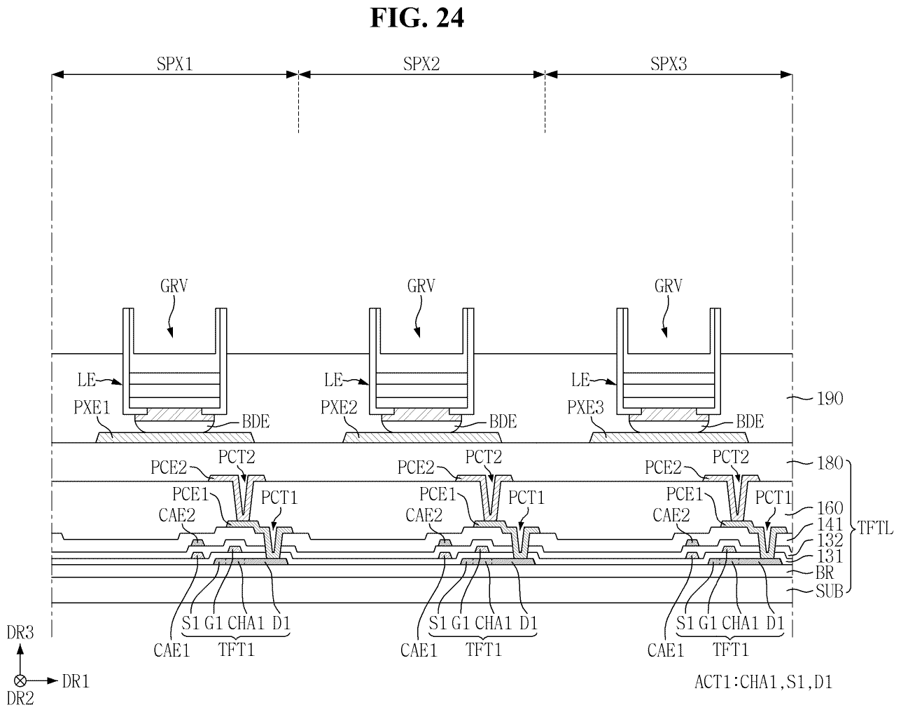

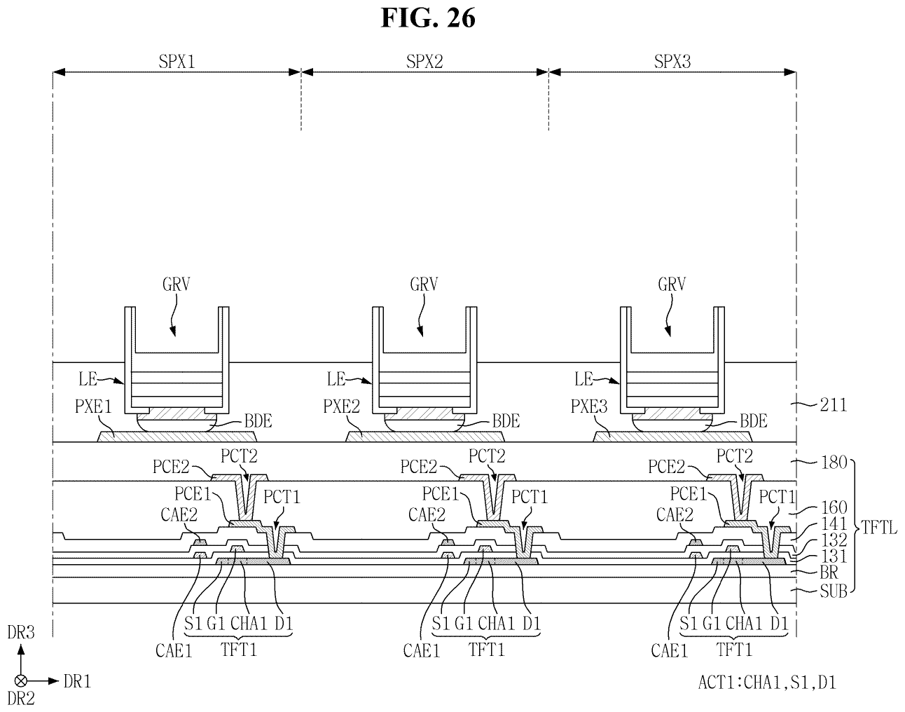

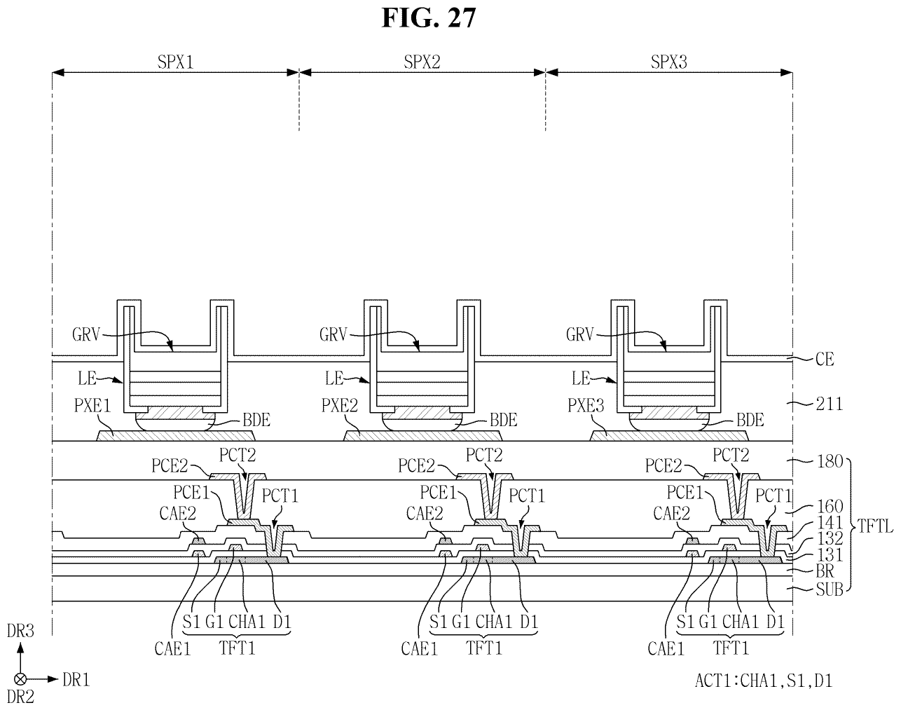

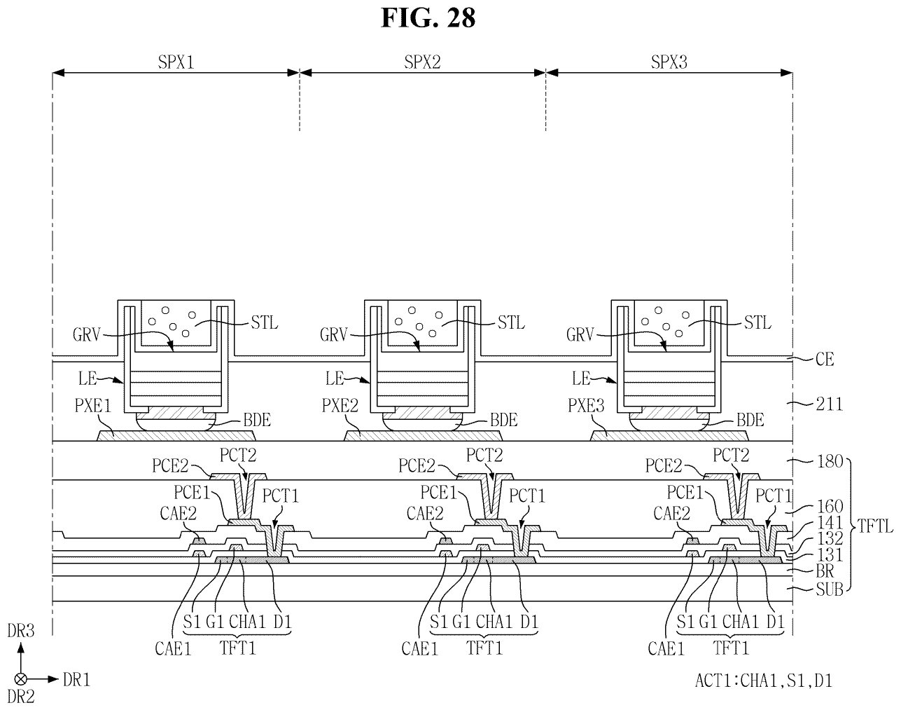

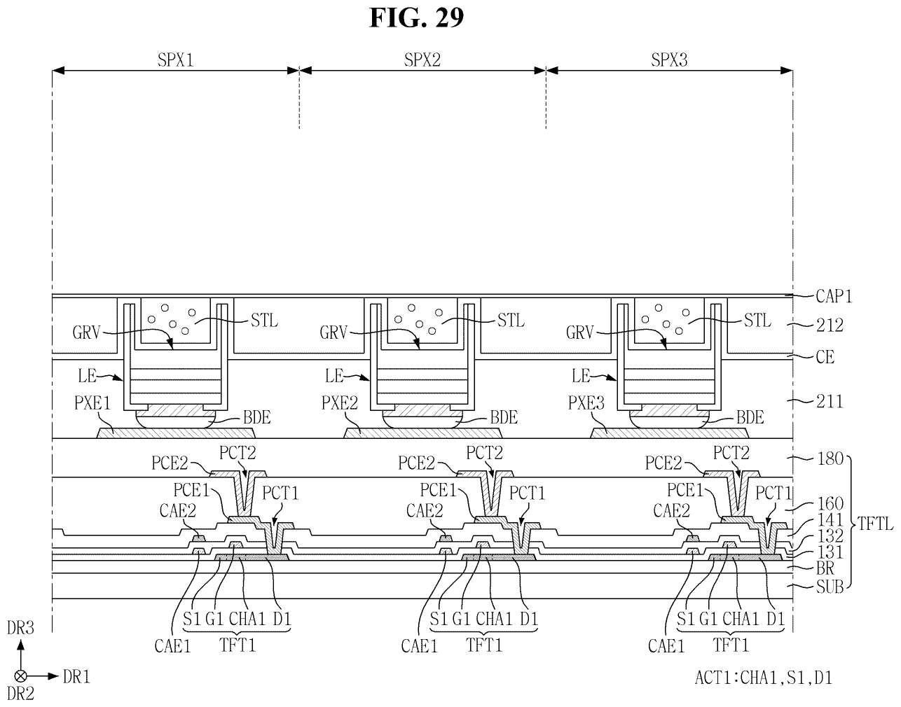

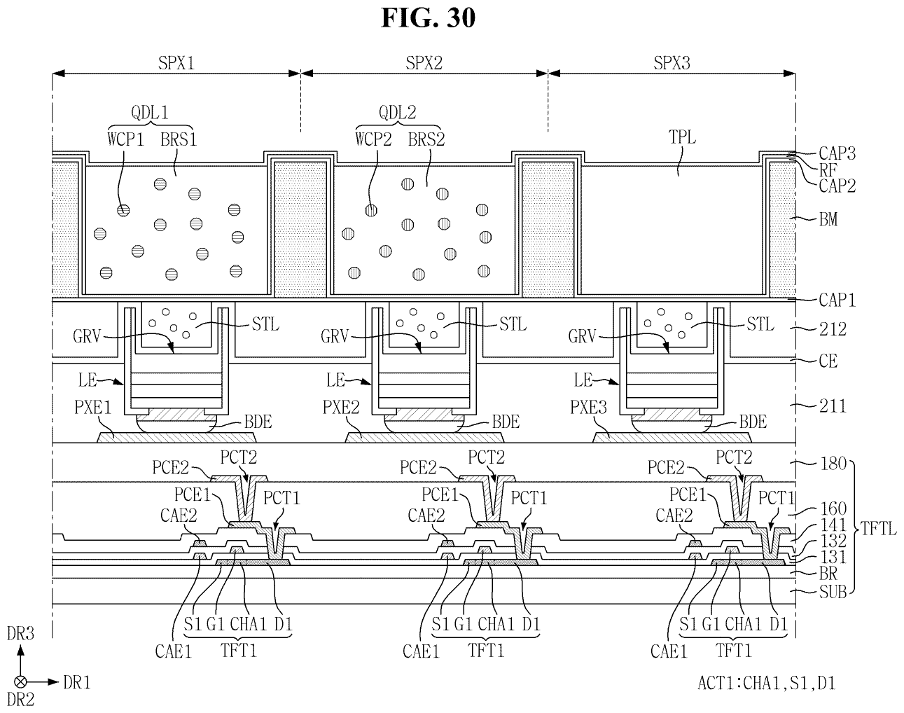

FIGS. 21 through 30 are cross-sectional views illustrating a method of manufacturing a display device according to one or more embodiments. For example, FIGS. 21 through 30 sequentially show operations for manufacturing the display panel 100 according to the embodiment of FIG. 8.

A method of manufacturing a display panel 100 according to one or more embodiments, for example, a display panel 100 according to at least one of the embodiments of FIGS. 9, 10, and 20 may be substantially the same as or similar to the method of manufacturing the display panel 100 according to the embodiment of FIG. 8. However, when a display panel 100 including an additional element, layer, or pattern compared with the display panel 100 according to the embodiment of FIG. 8 is manufactured, a process for forming the additional element, layer, or pattern may be additionally performed.

Referring to FIGS. 8 through 21, first, a thin-film transistor layer TFTL including a substrate SUB and thin-film transistors TFT1 may be formed, and pixel electrodes PXE1 through PXE3 may be formed on the thin-film transistor layer TFTL. For example, the substrate SUB may be prepared, and the thin-film transistor layer TFTL may be formed based on the substrate SUB. The forming of the thin-film transistor layer TFTL may include forming circuit elements (e.g., the thin-film transistors TFT1 and capacitors C1 including first capacitor electrodes CAE1 and second capacitor electrodes CAE2) and wirings on the substrate SUB.

Once the thin-film transistor layer TFTL is formed, a pixel electrode may be formed in each subpixel area. For example, a first pixel electrode PXE1, a second pixel electrode PXE2, and a third pixel electrode PXE3 may be formed in a first subpixel area for forming a first subpixel SPX1, a second subpixel area for forming a second subpixel SPX2, and a third subpixel area for forming a third subpixel SPX3, respectively. The pixel electrodes PXE1 through PXE3 may be formed by a process of forming a single-layer or multilayer conductive layer including at least one conductive material and a process of etching the conductive layer.

Referring to FIGS. 8 through 22, light emitting elements LE may be placed on the pixel electrodes PXE1 through PXE3. For example, the light emitting elements LE, each including a first semiconductor layer SEM1, an active layer MQW, and a second semiconductor layer SEM2, may be prepared and may be placed on the pixel electrodes PXE1 through PXE3 such that the second semiconductor layer SEM2 faces upward.

In one or more embodiments, the light emitting elements LE may be light emitting elements LE according to at least one of the embodiments of FIGS. 11 through 19. For example, the light emitting elements LE may include bonding electrodes BDE disposed under body portions CBD. In this case, the light emitting elements LE may be bonded onto the pixel electrodes PXE1 through PXE3 using the bonding electrodes BDE.

In one or more embodiments, the light emitting elements LE without grooves GRV may be prepared and placed on the pixel electrodes PXE1 through PXE3. For example, the second semiconductor layer SEM2 of each of the light emitting elements LE may include a first portion SEM2A and a second portion SEM2B sequentially disposed on the active layer MQW. A doping concentration of the first portion SEM2A of the second semiconductor layer SEM2 may be higher than a doping concentration of the second portion SEM2B of the second semiconductor layer SEM2.

Referring to FIGS. 8 through 23, a polymer layer 190 may be formed on the thin-film transistor layer TFTL. For example, the polymer layer 190 may be formed on the thin-film transistor layer TFTL by applying a polymer around the light emitting elements LE.

In one or more embodiments, the polymer layer 190 may be formed to have a height substantially equal or similar to that of the light emitting elements LE and may cover side surfaces of the light emitting elements LE, but the present disclosure is not limited thereto. The polymer layer 190 may protect the thin-film transistor layer TFTL during a subsequent process (e.g., an etching process for forming a groove GRV in each of the light emitting elements LE).

Referring to FIGS. 8 through 24, a groove GRV may be formed in each of the light emitting elements LE by etching the light emitting elements LE. For example, the second semiconductor layer SEM2 of each of the light emitting elements LE may be etched to expose the first portion SEM2A of the second semiconductor layer SEM2, thereby forming the groove GRV in each of the light emitting elements LE.

In one or more embodiments, only the second semiconductor layer SEM2 from among the second semiconductor layer SEM2 and a protective layer INS may be selectively etched to a certain depth or more by utilizing a difference in etch selectivity between the second semiconductor layer SEM2 and the protective layer INS. For example, the groove GRV may be formed in the second semiconductor layer SEM2 by etching the second semiconductor layer SEM2 to a depth greater than a depth or thickness of the second portion SEM2B of the second semiconductor layer SEM2 so that the first portion SEM2A of the second semiconductor layer SEM2 can be appropriately exposed. In the process of etching the second semiconductor layer SEM2, the second portion SEM2B of the second semiconductor layer SEM2 may partially remain around the protective layer INS or may be completely removed. The polymer layer 190 may also be etched in the process of etching the second semiconductor layer SEM2, and thus a height of the polymer layer 190 may be lowered.

In one or more embodiments, when a light transmission pattern is to be formed in the groove GRV, a process for forming the light transmission pattern may be additionally performed. For example, the light transmission pattern may be formed on a bottom surface of the groove GRV by performing a texturing process and/or the like.

Referring to FIGS. 8 through 25, the polymer layer 190 may be removed. For example, the polymer layer 190 may be removed by performing an ashing process and/or the like.

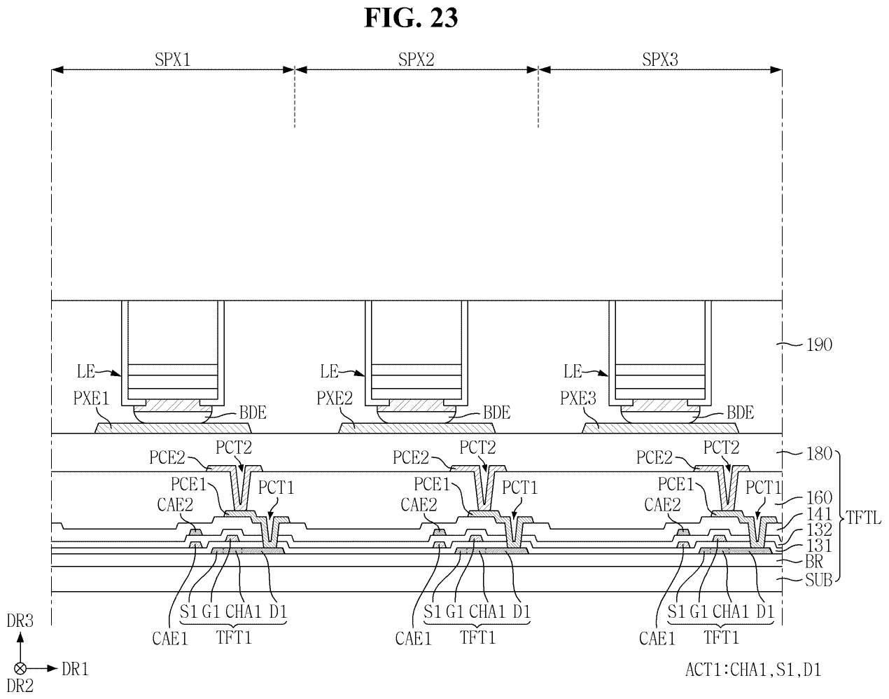

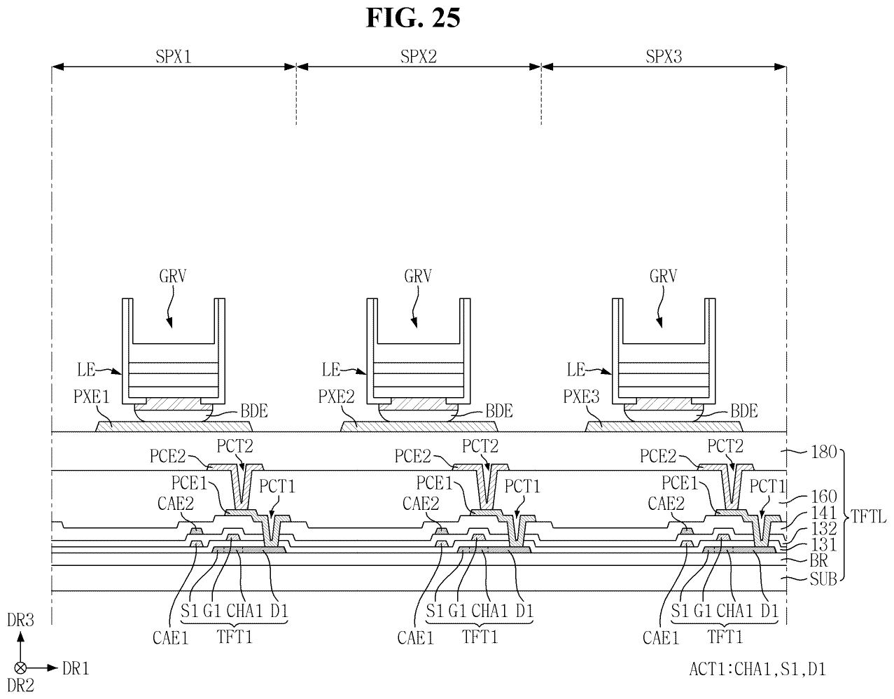

In one or more embodiments, the polymer layer 190 may not be formed. In this case, the process of forming the polymer layer 190 illustrated in FIG. 23 and the process of removing the polymer layer 190 illustrated in FIG. 25 may be omitted.

Referring to FIGS. 8 through 26, a third organic layer 211 may be formed on the thin-film transistor layer TFTL. For example, the third organic layer 211 may be formed on the thin-film transistor layer TFTL by applying an organic insulating material around the light emitting elements LE.

In one or more embodiments, the third organic layer 211 may be formed to a height smaller than a height of each of the light emitting elements LE. For example, the third organic layer 211 may be formed to a height smaller than a height of each groove GRV, but the present disclosure is not limited thereto. For example, the height of the third organic layer 211 may vary according to embodiments.

In one or more embodiments, the third organic layer 211 may be formed while the top of each light emitting element LE having the groove GRV is masked by a mask. Accordingly, the third organic layer 211 can be prevented from filling the inside of the grooves GRV.

Referring to FIGS. 8 through 27, a common electrode CE may be formed on the third organic layer 211 and the light emitting elements LE. For example, the common electrode CE may be formed entirely in a display area DA using a transparent conductive material such as ITO. In one or more embodiments, the common electrode CE may be thin enough to have a surface profile according to the shape of each groove GRV and may have a cross-sectional shape corresponding to that of the groove GRV on each of the light emitting elements LE. For example, the common electrode CE may define each groove GRV together with the light emitting elements LE. The common electrode CE may be formed inside and/or on each groove GRV to contact the first portion SEM2A of the second semiconductor layer SEM2 that corresponds to a high-doped layer.

Referring to FIGS. 8 through 28, light scattering layers STL may be formed on the common electrode CE. For example, the groove GRV of each light emitting element LE may be filled with a light scattering layer STL including light scatterers SCT.

Referring to FIGS. 8 through 29, a fourth organic layer 212 may be formed on the common electrode CE. For example, the fourth organic layer 212 may be formed by applying an organic insulating material around the light emitting elements LE to alleviate a step difference caused by the light emitting elements LE. Accordingly, the top of a light emitting element layer including the light emitting elements LE, the common electrode CE, and the light scattering layers STL can be planarized.

After the fourth organic layer 212 is formed, a first capping layer CAP1 may be formed. For example, the first capping layer CAP1 may be formed by applying an inorganic insulating material to the entire display area DA in which the light emitting elements LE, the common electrode CE, the light scattering layers STL, and the fourth organic layer 212 are formed.

Referring to FIGS. 8 through 30, a light blocking layer BM, a first light conversion layer QDL1, a second light conversion layer QDL2, and a light transmission layer TPL may be formed on the light emitting element layer. For example, after the light blocking layer BM is formed on the first capping layer CAP1 using a light blocking material, a second capping layer CAP2 may be formed using an inorganic insulating material to cover the light blocking layer BM, etc. Then, a reflective layer RF may be selectively formed on the second capping layer CAP2. Next, the first light conversion layer QDL1, the second light conversion layer QDL2, and/or the light transmission layer TPL may be formed in each subpixel area where a subpixel SPX is formed, and a third capping layer CAP3 may be formed using an inorganic insulating material to cover the first light conversion layer QDL1, the second light conversion layer QDL2, and the light transmission layer TPL.

The formation order of the light blocking layer BM, the first light conversion layer QDL1, the second light conversion layer QDL2, and the light transmission layer TPL may vary according to embodiments. For example, the first light conversion layer QDL1, the second light conversion layer QDL2, and the light transmission layer TPL may be formed first, and then the light blocking layer BM may be formed according to a process method used to form the first light conversion layer QDL1, the second light conversion layer QDL2, and the light transmission layer TPL.

When a display panel 100 further including color filters CF, etc. as illustrated in FIG. 8 is manufactured, a subsequent process for forming the color filters CF, etc. on the third capping layer CAP3 may be performed. For example, a fifth organic layer 213, the color filters CF, and a sixth organic layer 214 may be sequentially formed on the third capping layer CAP3.

As described above, a display device 10 according to one or more embodiments may include a light emitting element LE including a groove GRV in a portion where a second semiconductor layer SEM2 is disposed, a common electrode CE disposed on the light emitting element LE, and a light scattering layer STL disposed on the common electrode CE and filling the groove GRV. According to the display device 10 and a method of manufacturing the display device 10 according to one or more embodiments, light generated in the light emitting element LE can be appropriately scattered or diffused, and light emitted from the light emitting element LE can be appropriately transmitted or concentrated to above the light emitting element LE. For example, according to one or more embodiments, the proportion of light transmitted to a first light conversion layer QDL1, a second light conversion layer QDL2, and/or a light transmission layer TPL in the light emitted from the light emitting element LE can be increased.

In addition, according to one or more embodiments, because the groove GRV is formed by etching the second semiconductor layer SEM2, a distance between an active layer MQW and a light output surface (e.g., a bottom surface of the groove GRV) of the light emitting element LE can be reduced. Accordingly, the light output efficiency of the light emitting element LE can be increased.

In one or more embodiments, the groove GRV of the light emitting element LE may be formed to a depth that can expose a high-doped layer of the second semiconductor layer SEM2 (e.g., a first portion SEM2A of the second semiconductor layer SEM2). For example, the bottom surface of the groove GRV of the light emitting element LE may be located at a height corresponding to that of the first portion SEM2A of the second semiconductor layer SEM2 (e.g., at a distance or height of about 0.5 to 1.5 μm from the active layer MQW). The light emitting element LE may contact the common electrode CE inside and/or on the groove GRV. For example, the common electrode CE may be directly disposed on the first portion SEM2A of the second semiconductor layer SEM2 on the bottom surface of the groove GRV. According to the display device 10 and the method of manufacturing the display device 10 according to one or more embodiments, the ohmic formation between the light emitting element LE and the common electrode CE can be improved, and the contact resistance between them can be reduced. Accordingly, the driving voltage and power consumption of the display device 10 can be improved and/or optimized.

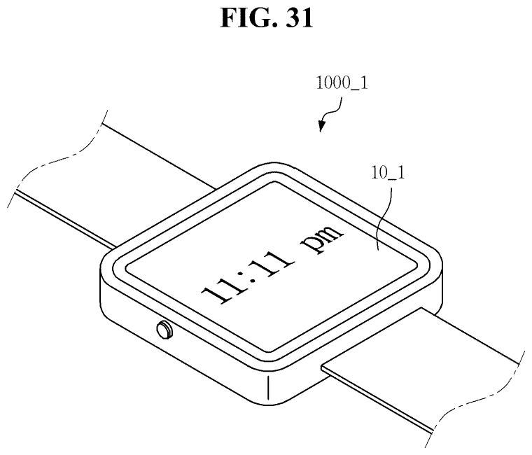

FIG. 31 is an example view of a smart watch including a display device according to one or more embodiments. Referring to FIG. 31, a display device 10_1 according to one or more embodiments may be applied to a smart watch 1000_1 which is one of smart devices.

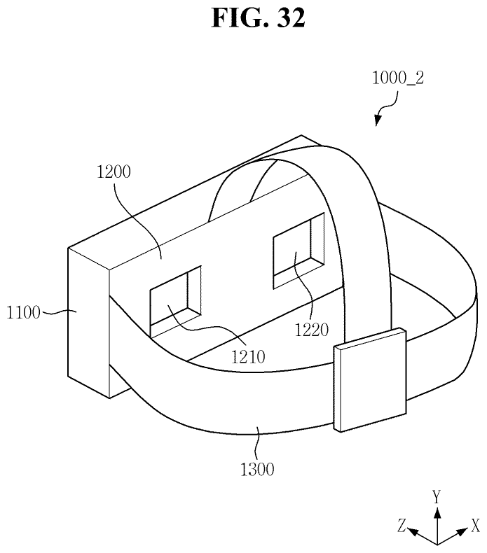

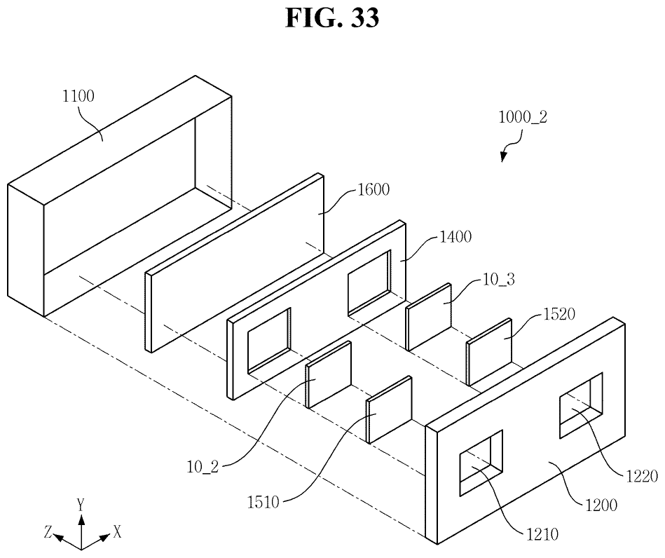

FIGS. 32 and 33 are example views of a virtual reality (VR) device including a display device according to one or more embodiments.

Referring to FIGS. 32 and 33, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 32 and 33, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

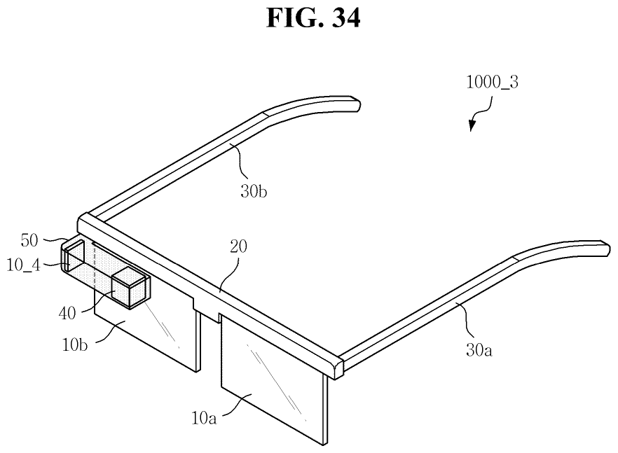

The head mounted band 1300 fixes the display device housing 1100 to a user's head so that the first eyepiece 1210 and the second eyepiece 1220 of the housing cover 1200 are kept placed on the user's left and right eyes, respectively. When the housing cover 1200 is implemented to be lightweight and small, the head mounted display device 1000_2 may include an eyeglass frame as illustrated in FIG. 34 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, and/or a high-definition multimedia interface (HDMI) terminal, and the wireless communication module may be a 5G communication module, a 4G communication module, a Wi-Fi module, and/or a Bluetooth module.

FIG. 34 is an example view of a VR device including a display device according to one or more embodiments. FIG. 34 illustrates a VR device 1000_3 to which a display device 10_4 according to one or more embodiments has been applied.

Referring to FIG. 34, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 34, a case where the VR device 1000_3 is a glasses-type display device including the eyeglass frame legs 30a and 30b is illustrated as an example. That is, the VR device 1000_3 according to the embodiment is not limited to the one illustrated in FIG. 34 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 34, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

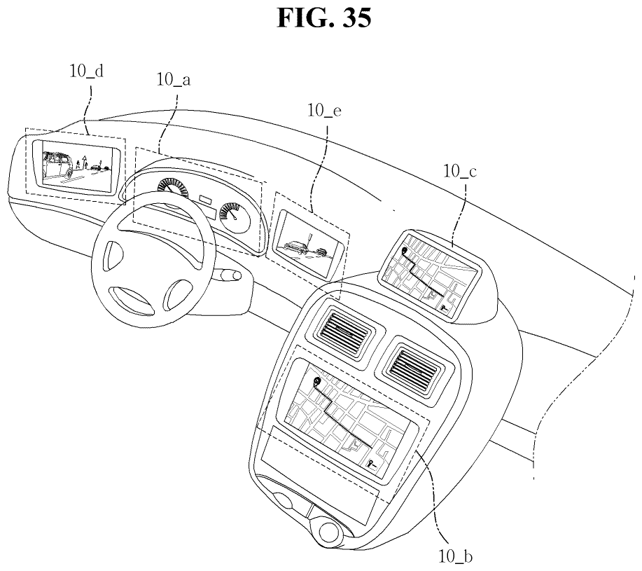

FIG. 35 is an example view illustrating a vehicle instrument cluster and center fascia including display devices according to one or more embodiments. FIG. 35 illustrates a vehicle to which display devices 10_a through 10_e according to one or more embodiments have been applied.

Referring to FIG. 35, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

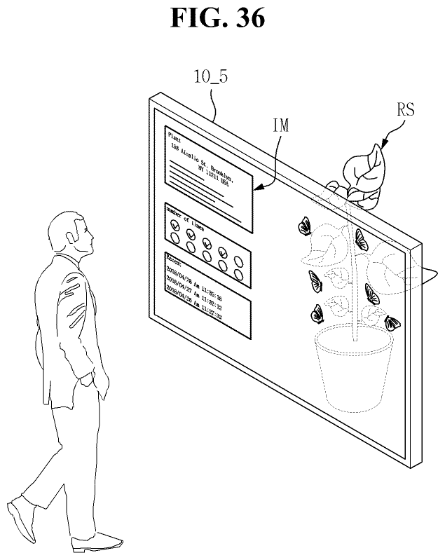

FIG. 36 is an example view of a transparent display device including a display device according to one or more embodiments.

Referring to FIG. 36, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

In concluding the detailed description, those skilled in the art will appreciate that many variations and modifications can be made to the embodiments without substantially departing from the principles, spirit, and scope of the present disclosure. Therefore, the embodiments of the present disclosure are used in a generic and descriptive sense only and not for purposes of limitation.

What is claimed is:

1. A display device comprising:
a pixel electrode;
a light emitting element comprising a first semiconductor layer, an active layer, and a second semiconductor layer sequentially located on the pixel electrode, a groove being in a portion of the light emitting element where the second semiconductor layer is located;
a common electrode on the light emitting element; and
a light scattering layer on the common electrode and filling the groove.

2. The display device of claim 1, wherein the second semiconductor layer comprises a first portion comprising a bottom surface of the groove and a second portion on the first portion, wherein a doping concentration of the first portion is higher than a doping concentration of the second portion.

3. The display device of claim 2, wherein the common electrode contacts the first portion of the second semiconductor layer.

4. The display device of claim 2, wherein the second portion of the second semiconductor layer comprises a portion of a sidewall of the groove.

5. The display device of claim 1, wherein the light emitting element further comprises a protective layer covering side surfaces of the first semiconductor layer, the active layer, and the second semiconductor layer, wherein a portion of the protective layer protrudes above a height of the second semiconductor layer and surrounds the groove.

6. The display device of claim 1, wherein the groove is formed at a position spaced from the active layer by 0.5 μm or more.

7. The display device of claim 6, wherein a bottom surface of the groove is located at a height of 0.5 to 1.5 μm from an upper surface of the active layer.

8. The display device of claim 1, wherein the common electrode has a shape corresponding to that of the groove, and a portion of the common electrode is inside the groove.

9. The display device of claim 8, wherein a bottom surface of the groove comprises a textured pattern, and the common electrode and the light scattering layer comprise a light transmission pattern having a shape corresponding to that of the textured pattern on the bottom surface of the groove.

10. The display device of claim 1, wherein the light emitting element further comprises a first reflective layer under the first semiconductor layer.

11. The display device of claim 10, wherein the first reflective layer comprises metal.

12. The display device of claim 10, wherein a portion of the first reflective layer covers side surfaces of the first semiconductor layer, the active layer, and the second semiconductor layer.

13. The display device of claim 10, wherein the light emitting element further comprises a second reflective layer covering side surfaces of the first semiconductor layer, the active layer, and the second semiconductor layer.

14. The display device of claim 13, wherein the second reflective layer comprises a distributed Bragg reflector.

15. The display device of claim 1, wherein the light scattering layer comprises light scatterers.

16. The display device of claim 15, wherein the light scattering layer further comprises wavelength conversion particles.

17. The display device of claim 1, further comprising a light conversion layer on the light emitting element and the light scattering layer, and comprising wavelength conversion particles.

18. A method of manufacturing a display device, the method comprising:
forming a thin-film transistor layer comprising a substrate and a thin-film transistor, and forming a pixel electrode on the thin-film transistor layer;
preparing a light emitting element comprising a first semiconductor layer, an active layer, and a second semiconductor layer, and placing the light emitting element on the pixel electrode such that the second semiconductor layer faces upward;
forming a groove in the light emitting element by etching the second semiconductor layer;
forming a common electrode on the light emitting element; and
forming a light scattering layer on the common electrode to fill the groove.

19. The method of claim 18, wherein the second semiconductor layer of the light emitting element comprises a first portion on the active layer and having a first doping concentration and a second portion on the first portion and having a second doping concentration lower than the first doping concentration, wherein the second semiconductor layer is etched to expose the first portion in the forming of the groove in the light emitting element.

20. The method of claim 19, wherein the common electrode contacts the first portion of the second semiconductor layer.

21. An electronic device for providing an image, comprising:
a display device comprising:
a pixel electrode;
a light emitting element comprising a first semiconductor layer, an active layer, and a second semiconductor layer sequentially located on the pixel electrode, a groove being in a portion of the light emitting element where the second semiconductor layer is located;
a common electrode on the light emitting element; and
a light scattering layer on the common electrode and filling the groove.
